(19) United States
(12) Patent Application Publication
(10) Pub. No.: US 2025/0207247 A1
(43) Pub. Date: Jun. 26, 2025

(54) METHODS THAT UTILIZE PHOTOSENSITIVE ORGANOMETALLIC OXIDES FORMED BY CHEMICAL VAPOR POLYMERIZATION

(71) Applicant: Tokyo Electron Limited, Tokyo (JP)

(72) Inventors: Kandabara Tapily, Albany, NY (US); Nobuo Matsuki, Niraski City (JP)

(21) Appl. No.: 19/048,395

(22) Filed: Feb. 7, 2025

Related U.S. Application Data
(63) Continuation-in-part of application No. 18/216,168, filed on Jun. 29, 2023.
(60) Provisional application No. 63/394,471, filed on Aug. 2, 2022.
(60) Provisional application No. 63/442,079, filed on Jan. 30, 2023.
(60) Provisional application No. 63/456,343, filed on Mar. 31, 2023.

(51) Int. Cl. C23C 16/04; C23C 16/50; C23C 16/56; G03F 7/00; G03F 7/004; G03F 7/16; H01L 21/027; H01L 21/311

(52) U.S. Cl. CPC C23C 16/045; C23C 16/50; C23C 16/56; G03F 7/0042; G03F 7/167; G03F 7/168; G03F 7/70033; H01L 21/0271; H01L 21/31144

(57) ABSTRACT

New gap fill materials and methods for filling gaps within patterned layers are provided herein. In various embodiments, a non-solid organometallic oxide polymer containing liquid-like oligomer units is deposited on a patterned layer via chemical vapor polymerization (CVP). The patterned layer comprises a plurality of structures, which are spaced apart and separated by gaps. During deposition, the liquid-like oligomer units flow into the gaps between the plurality of structures to completely fill the gaps with the non-solid organometallic oxide polymer. Heat-treating the semiconductor substrate further polymerizes the non-solid organometallic oxide polymer to form a photosensitive organometallic oxide polymer film on the patterned layer and within the gaps between the plurality of structures.

This application is a Continuation-in-Part (CIP) of U.S. patent application Ser. No. 18/216,168, filed Jun. 29, 2023, which claims priority to U.S. Provisional Patent Application Ser. No. 63/394,471, filed Aug. 2, 2022, U.S. Provisional Patent Application Ser. No. 63/442,079, filed Jan. 30, 2023, and U.S. Provisional Patent Application Ser. No. 63/456,343, filed Mar. 31, 2023, each of which is entitled “Method of Forming Photosensitive Organometallic Oxides by Chemical Vapor Polymerization”; the disclosures of which are expressly incorporated herein, in their entirety, by reference.

### TECHNICAL FIELD

The present invention relates generally to extreme ultraviolet (EUV)-active photoresist films, and, in particular embodiments, to methods of forming EUV-active films and methods of using EUV-active films to fill gaps in a patterned layer and to form contact holes in self-aligned multiple patterning (SAMP) processes.

### BACKGROUND

Generally, a semiconductor device, such as an integrated circuit (IC) is fabricated by sequentially depositing and patterning layers of dielectric, conductive, and semiconductor materials over a semiconductor substrate to form a network of electronic components and interconnect elements (e.g., transistors, resistors, capacitors, metal lines, contacts, and vias) integrated in a monolithic structure. At each successive technology node, the minimum feature sizes are shrunk to reduce cost by roughly doubling the component packing density. As geometries continue to shrink, the technical challenges to forming structures on substrates increase. These challenges are particularly evident in the photolithography and etch process areas.

Extreme ultraviolet (EUV) lithography is a lithography technique used to pattern photoresist films with EUV radiation. EUV lithography offers significant advantages in patterning sub-10 nm features with its high optical resolution. However, one major engineering challenge for EUV lithography is that photoresists developed for conventional photolithography systems may not satisfy the cost and/or quality requirements for patterning sub-10 nm features. For example, chemically amplified resist (CAR) or similar polymer resists, which are commonly used in 193 nm lithography, are typically produced using liquid based spin-on techniques that consume a significant amount of complex metal cluster precursors, resulting in very high cost. CARs also tend to have low absorption coefficients at 13.5 nm, and thus, may suffer poor sensitivity. Further, the diffusion of photo-activated species in CARs may cause blurring and increase line-edge roughness (LER) in the subsequently formed pattern.

As an alternative to CARs, vapor-deposited metal oxide-containing films have been investigated for use as EUV-active hardmasks in EUV lithography techniques. For example, U.S. Pat. No. 9,996,004, entitled “EUV Photopatterning of Vapor-Deposited Metal Oxide-Containing Hardmasks”, describes various processes for forming metal oxide-containing hardmasks utilized for EUV patterning. In the '004 Patent, an EUV-sensitive metal oxide-containing film is vapor deposited on a semiconductor substrate by chemical vapor deposition (CVD) or atomic layer deposition (ALD). During the deposition process, an organotin oxide precursor is reacted with a carbon dioxide-containing plasma at a relatively high deposition temperature (in one example, between 250° C. and 350° C.) to deposit the EUV-sensitive metal oxide-containing film on the semiconductor substrate. After CVD/ALD deposition, the metal oxide-containing film is transferred to an EUV patterning tool and patterned via direct EUV exposure (i.e., without the use of a photoresist), followed by pattern development, to form a metal oxide-containing hardmask. The processes described in the '004 Patent suffer from various disadvantages. For example, the deposition processes described in the '004 Patent react various organotin oxide precursors with an oxidizer (e.g., carbon dioxide or carbon monoxide) in a typical CVD/ALD process to form a solid metal oxide-containing film on the semiconductor substrate. The oxidizer utilized within the CVD/ALD deposition process increases the density of the metal oxide-containing film and decomposes the Sn—R bonds (where —R is —CxHy, —OCxHy, —Cl or —NCxHy) in organo tin precursors, which creates weak and unstable bonds (for example, Sn—OH and Sn—O—Sn bonds), which deteriorate EUV photosensitivity of the subsequently formed hardmask.

Self-aligned multiple patterning (SAMP) processes, such as self-aligned double patterning (SADP), self-aligned triple patterning (SATP) and self-aligned quadruple patterning (SAQP), have been developed to reduce feature sizes beyond what is directly achievable by conventional lithography techniques, including EUV lithography. SAMP processes utilize mandrels, sidewall spacers and selective etching to form structures on a substrate surface at pitches that are significantly less than the original photolithography pitch. As such, SAMP processes utilize sidewall spacers to increase the structure density on the substrate surface.

In SADP processes, spacers are typically formed as side wall structures adjacent to core structures or “mandrels” on a substrate being processed. The mandrels may be formed on the substrate through known photolithography techniques. Sidewall spacers are then formed adjacent to the mandrels. The core material (or mandrels) may then be removed, leaving two sidewall spacers for each mandrel. The core removal process is typically called a mandrel pull and is often performed by a plasma etch process, such as a reactive ion etch (RIE) process. The sidewall spacers left on the substrate surface after the mandrel pull process form a pattern on the substrate surface having a smaller pitch than the pitch of the originally formed mandrels. In SATP and SAQP processes, additional sidewall spacers of differing materials may be formed adjacent the first sidewall spacers to further reduce the pitch of the subsequently formed pattern.

FIGS. 1A-1F illustrate a conventional SADP process flow that can be used to form a patterned layer on a substrate. As shown in FIG. 1A, a substrate 100 is provided including a core material layer 110 formed above one or more underlying layers 105 (e.g., various patterned and unpatterned layers formed during substrate processing). The core material layer 110 is the layer within which the mandrels utilized in the SADP process flow will eventually be formed. The core material layer 110 may include a wide variety of materials. In one example, the core material layer 110 may be a silicon nitride (SiN) layer. However, other materials, including but not limited to, oxide, nitride, carbon, amorphous silicon, or metallic materials, may also be utilized to form the core material layer 110. The substrate 100 further includes an adhesion layer 115 (such as, e.g., a silicon antireflective coating (SiARC) layer) and a patterned photo resist layer 120, as shown in FIG. 1A.

The patterned photo resist layer 120 is used as a mask to etch the adhesion layer 115 and the core material layer 110 to form the mandrels 125, as shown in FIG. 1B. After a spacer deposition layer 130 is formed over the substrate 100, as shown in FIG. 1C, the substrate 100 is subjected to a spacer etch and mandrel pull process to remove the mandrels 125, leaving the spacers 135 on either side of the mandrels. After forming a second spacer deposition layer 140 over the substrate 100, as shown in FIG. 1E, a gap fill material 145 may be deposited on the substrate 100 to fill the gaps (g) formed between the spacers 135 as shown in FIG. 1F. The gap fill material 145 is generally a spin-on material, such as spin-on glass (SOG), spin-on carbon (SOC) or another spin-on material, such as a silicon-based oxide, nitride, carbide, oxynitride, metallic-base oxide, or metallic-base nitride. Alternatively, the gap fill material 145 may be a silicon-based oxide, nitride, carbide, oxynitride, metallic-base oxide, metallic-base nitride, amorphous silicon or metallic material deposited by chemical vapor deposition (CVD) or atomic layer deposition (ALD).

Unfortunately, problems arise when conventional gap fill materials are used to fill narrow gaps or patterned layers with pitch less than 28 nm. For example, voids or bubbles may be created within the gap fill material 145 when spin-on materials are used to fill narrow gaps, as shown in FIG. 1F. CVD and ALD deposited gap fill materials also present challenges. Thus, it would be desirable to provide new gap fill materials for filling narrow gaps within patterned layers.

### SUMMARY

Embodiments of the present disclosure provide improved process flows and methods of forming a photosensitive organometallic oxide polymer film on a semiconductor substrate. Further embodiments utilize the photosensitive organometallic oxide polymer film in subsequent processing steps to form an EUV-active photoresist on a substrate, fill gaps within a patterned layer and/or create features (such as, e.g., holes, trenches, etc.) within a patterned layer.

In various embodiments of the present disclosure, chemical vapor polymerization (CVP) is utilized to deposit a non-solid, organometallic oxide polymer on a patterned layer formed on a semiconductor substrate. The patterned layer may have a plurality of structures, which are spaced apart and separated by narrow gaps. The non-solid organometallic oxide polymer layer is deposited onto the patterned layer using a low temperature, low ion energy plasma process, which exposes the semiconductor substrate to a plasma-excited vapor comprising a metal precursor having carbon-carbon double bonds. The low temperature, low ion energy plasma process forms a non-solid, organometallic oxide polymer layer (containing liquid-like oligomer units) having carbon-carbon bonds on the patterned layer and within the gaps formed between the plurality of structures. The semiconductor substrate is then subjected to a heat treatment (for example, a thermal bake) to further polymerize the non-solid organometallic oxide polymer layer and form a photosensitive organometallic oxide polymer film with carbon-carbon bonds on the patterned layer and within the gaps.

The methods disclosed herein provide various advantages over conventional gap fill materials and methods for filling narrow gaps within a patterned layer provided on a semiconductor substrate. Unlike conventional methods that utilize spin-on materials, the methods disclosed herein utilize a low temperature, low ion energy plasma process to form a non-solid, organometallic oxide polymer on the patterned layer that completely fills the gaps between the plurality of structures. Upon subsequent heat treatment, the non-solid, organometallic oxide polymer deposited on the patterned layer and within the gaps is further polymerized to form a photosensitive organometallic oxide polymer film, which can be selectively exposed to extreme ultraviolet (EUV) radiation and selectively etched to create one or more features (such as, e.g., holes, trenches, etc.) within the patterned layer.

According to one embodiment, a method is provided herein for filling gaps within a patterned layer formed on a semiconductor substrate. The method may generally begin by providing the semiconductor substrate, wherein the patterned layer formed on the semiconductor substrate comprises a plurality of structures, which are spaced apart and separated by gaps. The method may further include depositing a non-solid organometallic oxide polymer containing liquid-like oligomer units on the patterned layer via chemical vapor polymerization (CVP), wherein the liquid-like oligomer units flow into the gaps between the plurality of structures during said depositing, and wherein a capillary effect within the gaps causes the liquid-like oligomer units to completely fill the gaps with the non-solid organometallic oxide polymer. The method may further include heat-treating the semiconductor substrate to further polymerize the non-solid organometallic oxide polymer and form a photosensitive organometallic oxide polymer film on the patterned layer and within the gaps between the plurality of structures. In some embodiments, the photosensitive organometallic oxide polymer film may contain a central metal atom of tin (Sn), zirconium (Zr), indium (In), antimony (Sb), bismuth (Bi), zinc (Zn), hafnium (Hf), or aluminum (Al), or combinations thereof.

According to another embodiment, a method utilized in a self-aligned multi-patterning (SAMP) process flow may generally begin by forming a patterned layer on one or more underlying layers formed on a semiconductor substrate. The patterned layer may comprise a plurality of structures, which are formed during the SAMP process flow and separated by gaps. The method may further include depositing a non-solid organometallic oxide polymer containing liquid-like oligomer units on the patterned layer via chemical vapor polymerization (CVP), wherein the liquid-like oligomer units flow into the gaps between the plurality of structures during said depositing, and wherein a capillary effect within the gaps causes the liquid-like oligomer units to completely fill the gaps with the non-solid organometallic oxide polymer. The method may further include heat-treating the semiconductor substrate to further polymerize the non-solid organometallic oxide polymer and form a photosensitive organometallic oxide polymer film on the patterned layer and within the gaps between the plurality of structures. In some embodiments, the photosensitive organometallic oxide polymer film may contain a central metal atom of tin (Sn), zirconium (Zr), indium (In), antimony (Sb), bismuth (Bi), zinc (Zn), hafnium (Hf), or aluminum (Al), or combinations thereof.

After forming the photosensitive organometallic oxide polymer film on the patterned layer and within the gaps between the plurality of structures, the method may further include selectively exposing the photosensitive organometallic oxide polymer film to extreme ultraviolet (EUV) radiation, wherein said selectively exposing changes an etch selectivity of a portion of the photosensitive organometallic oxide polymer film formed within one or more of the gaps. The method may further include selectively etching the photosensitive organometallic oxide polymer film, wherein said selectively etching removes the portion of the photosensitive organometallic oxide polymer film from the one or more of the gaps to create one or more features on the one or more underlying layers.

In some embodiments, said selectively etching may remove the portion of the photosensitive organometallic oxide polymer film from the one or more of the gaps to create a contact hole pattern on the one or more underlying layers. In such embodiments, the method may further include utilizing the contact hole pattern to form contact holes within the one or more underlying layers.

In the methods disclosed above, said depositing the non-solid organometallic oxide polymer may include exposing the semiconductor substrate to a plasma-excited vapor comprising a metal precursor having carbon-carbon double bonds to form the non-solid organometallic oxide polymer on the patterned layer and within the gaps between the plurality of structures. In some embodiments, said exposing the semiconductor substrate to the plasma-excited vapor may include maintaining an ion energy of less than 50 eV in the plasma-excited vapor and maintaining a substrate temperature of less than 150° C. during the exposing. In other embodiments, said exposing the semiconductor substrate to the plasma-excited vapor may include maintaining an ion energy of between 0 eV and 5 eV in the plasma-excited vapor, and maintaining a substrate temperature within a range between −50° C. and 0° C. during the exposing.

A wide variety of metal precursors may be utilized in the methods disclosed above to form the non-solid organometallic oxide polymer on the patterned layer and within the gaps between the plurality of structures. The metal precursor used within the plasma-excited vapor may generally include a metal alkoxide.

In some embodiments, the metal precursor may contain tin (Sn). In one example, the metal precursor may have the formula Sn_{α}O_{β} (O—CₘHₙ)ΓCₓH_{y}, where m, n, and α are arbitrary integers of 1 or more, β, Γ, x, and y are arbitrary integers of 0 or more, and β and Γ are not 0 at the same time. For example, the metal precursor may include SnR1(O—R2)₃, SnR1₂(O—R2)₂, or SnHR1(O—R2)₂, where R1: CH₃, C₂H₃, C₃H₅, C₄H₇, or C₆H₆, and R2: CH₃, C₂H₅, C₃H₇, or C₄H₉. In another example, the metal precursor may include SnCH₃^{t}Bu(O—^{t}Bu)₂, Sn^{t}Bu(O—^{t}Bu)₃, Sn^{t}Bu(O—C₃H₇)₃, Sn^{t}Bu(O—C₂H₅)₃, Sn^{t}Bu(O—CH₃)₃, SnCH₃C₂H₃(O—^{t}Bu)₂, or SnCH₃(C₂H₃)(O—CH₃)₂. In yet another example, the metal precursor may have the formula SnₓC_{y}H_{z}, where x, y, and z are arbitrary integers of 1 or more. For example, the metal precursor may be selected from the group consisting of Sn(CH₃)₄, Sn(C₂H₅)₄, SnH(CH₃)₃, and SnH(C₂H₅)₃. In further examples, the metal precursor may include Sn(C₂H₄O₂) or Sn(OR)₂, where R may be selected from CH₃, C₂H₅ and C₄H₉, or a mixture of Sn(N(CH₃)₂)₄ and HOCH₂CH₂OH.

In other embodiments, the metal precursor may contain a metal (M) and have the formula M_{α}O_{β} (O—CₘHₙ)ΓCₓH_{y}, where m, n, and a are arbitrary integers of 1 or more, β, Γ, x, and y are arbitrary integers of 0 or more, and β and Γ are not 0 at the same time. Examples of metals (M) having a high EUV absorption coefficient include, but are not limited to, tin (Sn), zirconium (Zr), antimony (Sb), indium (In), bismuth (Bi), zinc (Zn), hafnium (Hf), and aluminum (Al).

In some embodiments, the plasma-excited vapor may further include an additive precursor. For example, when the metal precursor contains tin (Sn) and has the formula Sn_{α}O_{β} (O—CₘHₙ)ΓCₓH_{y}, the additive precursor added to the plasma-excited vapor may contain tin (Sn) and have a formula Sn_{α}CₓH_{y}, where m, n, and α are arbitrary integers of 1 or more. When the metal precursor contains a metal (M) and has the formula M_{α}O_{β} (O—CₘHₙ)ΓCₓH_{y}, the additive precursor added to the plasma-excited vapor may be: (a) a precursor containing a metal (M) and having a formula MαCxHy, where m, n, and α are arbitrary integers of 1 or more, and/or (b) a nitrogen containing precursor, such as nitrogen or an amine.

In the methods disclosed above, said heat-treating the semiconductor substrate may include heat-treating the semiconductor substrate to a substrate temperature between about 0° C. and about 400° C. to further polymerize the non-solid organometallic oxide polymer and form the photosensitive organometallic oxide polymer film with polymerized carbon-carbon bonds on the patterned layer and within the gaps between the plurality of structures. A wide variety of methods may be utilized to heat treat the semiconductor substrate. In one embodiment, said heat-treating the semiconductor substrate may utilize a plasma.

Various embodiments of methods are provided herein for filling narrow gaps within a patterned layer provided on the semiconductor substrate. Further embodiments of methods are provided herein for forming contact holes in a self-aligned multi-patterning process flow. Of course, the order of discussion of the different steps as described herein has been presented for clarity sake. In general, these steps can be performed in any suitable order. Additionally, although each of the different features, techniques, configurations, etc. herein may be discussed in different places of this disclosure, it is intended that each of the concepts can be executed independently of each other or in combination with each other. Accordingly, the present invention can be embodied and viewed in many different ways.

Note that this summary section does not specify every embodiment and/or incrementally novel aspect of the present disclosure or claimed inventions. Instead, this summary only provides a preliminary discussion of different embodiments and corresponding points of novelty over conventional techniques. For additional details and/or possible perspectives of the invention and embodiments, the reader is directed to the Detailed Description section and corresponding figures of the present disclosure as further discussed below.

### BRIEF DESCRIPTION OF THE DRAWINGS

A more complete understanding of the present inventions and advantages thereof may be acquired by referring to the following description taken in conjunction with the accompanying drawings, in which like reference numbers indicate like features. It is to be noted, however, that the accompanying drawings illustrate only exemplary embodiments of the disclosed concepts and are therefore not to be considered limiting of the scope, for the disclosed concepts may admit to other equally effective embodiments.

FIGS. 1A-1E illustrate one embodiment of self-aligned multi-patterning (SAMP) process flow that can be used to form a patterned layer on a substrate.

FIG. 1F illustrates a conventional gap fill method that can be used to fill the gaps formed in the patterned layer shown in FIG. 1E.

FIG. 2A illustrates an example process flow to form an EUV-active photoresist film on a surface of a semiconductor substrate in accordance with one embodiment of the present disclosure.

FIG. 2B illustrates example chemistry that can be utilized for the chemical vapor polymer deposition and heat treatment steps shown in FIG. 2A, including an example metal precursor that can be used during the plasma process step to form an example non-solid, organometallic oxide polymer layer on the substrate surface, and an example EUV-active photoresist film that can be formed during the subsequently performed heat treatment step.

FIG. 3A illustrates an example process flow to pattern and develop the EUV-active photoresist film formed in FIG. 2A.

FIG. 3B illustrates example reactions that occur during the EUV exposure and (optional) post exposure bake (PEB) steps shown in FIG. 3A.

FIG. 4 is a flowchart diagram illustrating one embodiment of a method that uses the techniques disclosed herein to fill gaps within a patterned layer formed on a semiconductor substrate in accordance with the present disclosure.

FIG. 5 illustrates an example process flow that uses the method shown in FIG. 4 to fill gaps within a patterned layer with a photosensitive organometallic oxide polymer film.

FIG. 6 is a flowchart diagram illustrating one embodiment of a method that uses the techniques disclosed herein to improve contact hole patterning in a self-aligned multi-patterning (SAMP) process flow in accordance with the present disclosure.

FIGS. 7A-7F illustrate another embodiment of a self-aligned multi-patterning (SAMP) process flow that can be used to form a patterned layer on a substrate.

FIGS. 8A-8F illustrate an example process flow that utilizes the method shown in FIG. 6 to fill gaps within a patterned layer with a photosensitive organometallic oxide polymer film and create contact holes within the patterned layer formed in FIG. 7F.

### DETAILED DESCRIPTION OF ILLUSTRATIVE EMBODIMENTS

Embodiments of the present disclosure provide improved process flows and methods of forming a photosensitive organometallic oxide polymer film on a semiconductor substrate. Further embodiments utilize the photosensitive organometallic oxide polymer film in subsequent processing steps to form an EUV-active photoresist on a substrate, fill gaps within a patterned layer and/or create features (such as, e.g., holes, trenches, etc.) within a patterned layer.

In the present disclosure, chemical vapor polymerization (CVP) is utilized to deposit a non-solid, organometallic oxide polymer onto a surface of a semiconductor substrate (or onto a patterned layer formed above the substrate surface). The non-solid organometallic oxide polymer layer is deposited onto the substrate surface using a low temperature, low ion energy plasma process, which exposes the substrate surface to a plasma-excited vapor comprising a metal precursor having carbon-carbon double bonds. The low temperature, low ion energy plasma process forms a non-solid, organometallic oxide polymer (containing liquid-like oligomer units) having carbon-carbon bonds on the substrate surface. The semiconductor substrate is then subjected to a heat treatment (e.g., a thermal bake) to further polymerize the non-solid organometallic oxide polymer and form a photosensitive organometallic oxide polymer film with carbon-carbon bonds. The photosensitive organometallic oxide polymer film disclosed herein can be exposed to extreme ultraviolet (EUV) radiation to induce changes in material properties that enable portions of the photosensitive organometallic oxide polymer film to be selectively removed during subsequent processing steps. This enables the photosensitive organometallic oxide polymer film disclosed herein to be utilized in a wide range of semiconductor processes.

In some embodiments, the techniques disclosed herein can be used to create an EUV-active photoresist comprising an organometallic moiety for use in EUV photolithographic processes. As discussed in more detail below, an EUV-active photoresist formed in accordance with the present disclosure provides numerous advantages over conventional photoresists typically used for EUV lithography, such as CARs and vapor-deposited metal oxide-containing films, such as those described in the '004 Patent.

In other embodiments, the techniques disclosed herein can be used to create a photosensitive organometallic oxide polymer film with improved gap filling properties, and may be particularly useful when filling narrow gaps between structures in a patterned layer. Unlike conventional spin-on materials, the low temperature, low ion energy plasma process disclosed herein can be used to deposit a non-solid, organometallic oxide polymer (containing liquid-like oligomer units) on the patterned layer in a manner that completely fills the gaps between the structures. Subsequent heat treatment further polymerizes the non-solid, organometallic oxide polymer deposited on the patterned layer and within the gaps to form a photosensitive organometallic oxide polymer film, which can be selectively exposed to EUV radiation and selectively etched to create features (such as, e.g., holes, trenches, etc.) within the patterned layer.

In some embodiments, the techniques disclosed herein can be used to improve contact hole patterning in a self-aligned multi-patterning (SAMP) process flow. For example, the low temperature, low ion energy plasma process disclosed herein can be used to deposit liquid-like oligomer units on a patterned layer and within the gaps between the plurality of structures (e.g., the mandrels, spacers, etc.) formed during the SAMP process flow. The liquid-like oligomer units deposited on and within the patterned layer are photosensitive and offer excellent gap fill properties, especially in the narrow gaps formed during the SAMP process flow. Subsequent heat treatment further polymerizes the liquid-like oligomer units to form a new organometallic compound (e.g., a photosensitive organometallic oxide polymer film) in the SAMP process flow. Upon EUV exposure, the material properties of the photosensitive organometallic oxide polymer film can be tuned to change the etch selectivity within select portions of the photosensitive organometallic oxide polymer film and enable grid patterning.

### Methods for Forming EUV-Active Photoresists

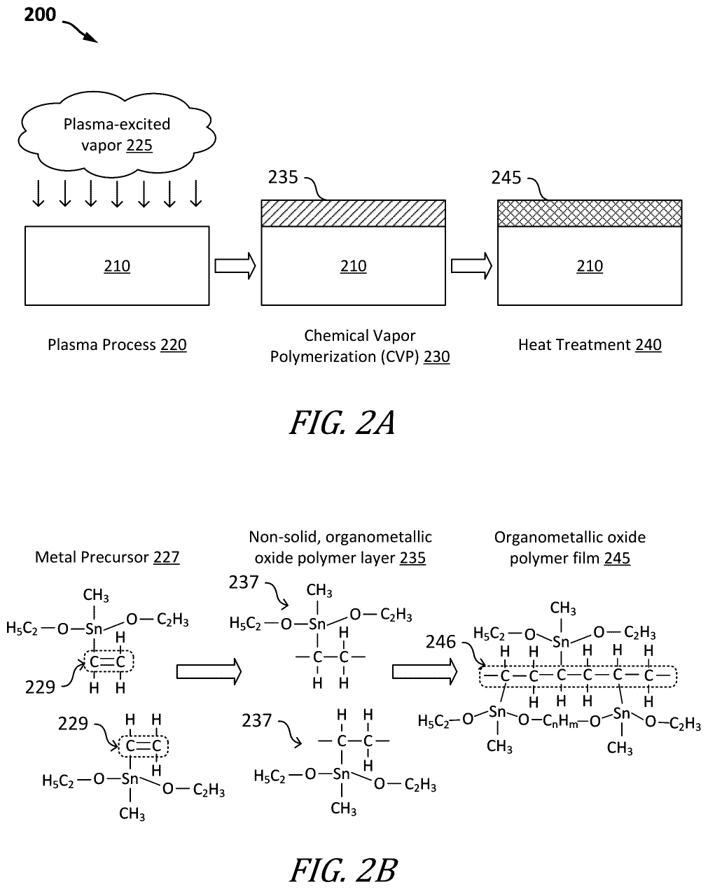

Turning now to the Drawings, FIG. 2A illustrates one embodiment of a process flow 200 used to form an EUV-active photoresist on a surface of a semiconductor substrate 210 in accordance with one embodiment of the present disclosure. The semiconductor substrate 210 may be any substrate for which the patterning of the substrate is desirable. For example, in one embodiment, the semiconductor substrate 210 may be a substrate having one or more semiconductor processing layers (all of which together may comprise the substrate) formed thereon. Thus, in one embodiment, the semiconductor substrate 210 may be a substrate that has been subject to multiple semiconductor processing steps which yield a wide variety of structures and layers, all of which are known in the substrate processing art, and which may be considered to be part of the substrate. For example, in one embodiment, the semiconductor substrate 210 may be a semiconductor wafer having one or more semiconductor processing layers formed thereon. The concepts disclosed herein may be utilized at any stage of the substrate process flow, for example any of the numerous photolithography steps which may be utilized to form a completed substrate.

As shown in FIG. 2A, process flow 200 begins by performing a low temperature, low ion energy plasma process 220 that exposes the surface of the semiconductor substrate 210 to a plasma-excited vapor 225 containing a metal precursor having carbon-carbon double bonds. In some embodiments, an additive precursor may also be included within the plasma-excited vapor 225. Examples of suitable metal precursors and additive precursors are discussed in more detail below. During the plasma process 220, the semiconductor substrate 210 is maintained at a relatively low substrate temperature (for example, a substrate temperature less than about 150° C., and more preferably, less than about 0° C.), while ions within the plasma-excited vapor 225 are maintained at a relatively low ion energy (for example, an ion energy less than about 50 eV, and more preferably, between about 0 eV and about 5 eV). Under these conditions, a non-solid organometallic oxide polymer layer 235 is deposited onto the surface of the semiconductor substrate 210 via chemical vapor polymerization (CVP) 230.

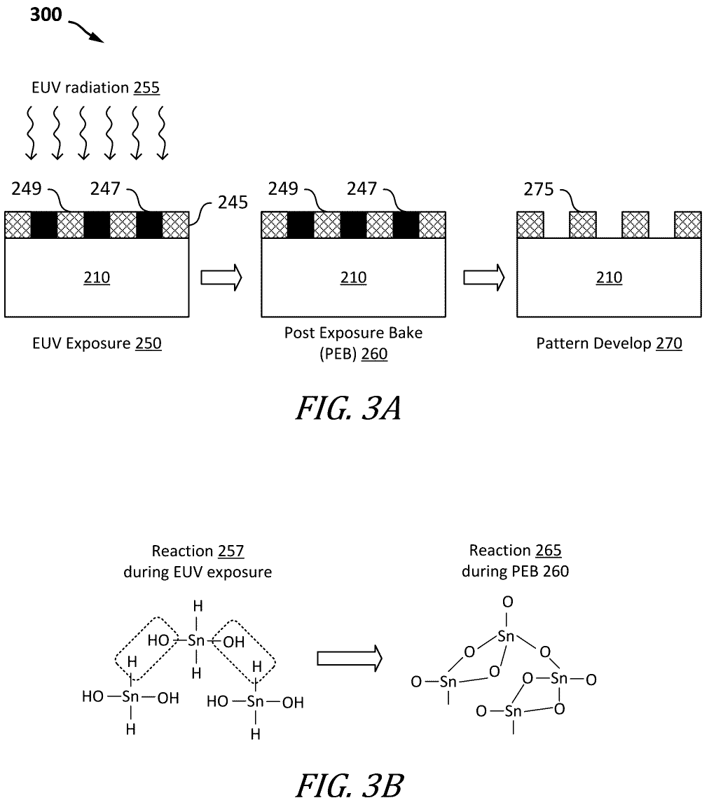

Once the non-solid organometallic oxide polymer layer 235 is deposited onto the substrate surface, the semiconductor substrate 210 is subjected to a heat treatment 240 (for example, a thermal bake) to further polymerize the non-solid organometallic oxide polymer layer 235 and form a photosensitive organometallic oxide polymer film 245 having carbon-carbon bonds on the substrate surface. The organometallic oxide polymer film 245 formed in accordance with the process flow 200 is an EUV-active photoresist film that can be patterned with EUV lithography and developed as shown, for example, in FIG. 3A and described below.

As noted above, the plasma process 220 shown in FIG. 2A is performed at relatively low substrate temperatures and ion energies. According to one embodiment, the substrate temperature during the plasma exposure can, for example, be less than about 150° C. For example, the substrate temperature during the plasma exposure can be between about 0° C. and about 50° C. In other embodiments, the substrate temperature during the plasma exposure can be less than 0° C. during the plasma exposure. For example, the substrate temperature during the plasma exposure can be between about −50° C. and about 0° C., between about −50° C. and about −25° C., or between about −25° C. and about 0° C. According to one embodiment, the ion energy of the ions within the plasma-excited vapor 225 can be about 50 eV. In other embodiments, the ion energy can be less than 50 eV, for example, between about 0 eV and about 50 eV or between about 0 eV and about 5 eV. It is contemplated that the use of ion energy between about 0 eV and about 5 eV is beneficial to minimize plasma damage to the non-solid organometallic oxide polymer layer 235 deposited onto the substrate surface during the plasma process 220.

The plasma process 220 shown in FIG. 2A can be performed within a wide variety of plasma processing systems and/or chambers. In some embodiments, the plasma process 220 may be performed within a capacitively coupled plasma (CCP) processing chamber. In some examples, a 13.56 MHz-60 MHz CCP source with power between about 10 W and about 500 W may be used to create plasma conditions that include an ion energy of about 50 eV (or less). A gas pressure within the CCP processing chamber can, for example, be between about 100 mTorr and about 20 Torr. The substrate temperature can be less than about 150° C., as set forth above.

In other embodiments, a plasma processing system containing a remote plasma source can be used to perform the plasma process 220 shown in FIG. 2A. Examples of such plasma processing systems include the use of remote plasma sources using radio frequency (RF), very high frequency (VHF), and microwave frequency (MWF). A plasma processing system containing a remote plasma source can include: (a) a vacuum chamber that is divided into a plasma space and a separate wafer space by a separation plate with plurality of holes, or (b) a plasma source that is attached to the vacuum chamber. A remote plasma source may be desirable in some embodiments, since it is effective in minimizing or eliminating exposure of the substrate to high energy ions.

The heat treatment 240 shown in FIG. 2A includes heat-treating the semiconductor substrate 210 containing the non-solid organometallic oxide polymer layer 235 formed thereon to further polymerize the non-solid organometallic oxide polymer layer 235 and form the photosensitive organometallic oxide polymer film 245 with polymerized carbon-carbon bonds. According to one embodiment, the semiconductor substrate 210 is heated to a substrate temperature between about 0° C. and about 400° C. during the heat treatment 240 step shown in FIG. 2A. For example, the semiconductor substrate 210 can be heated to, and maintained at, a substrate temperature: (a) between about 0° C. and about 50° C., (b) between about 50° C. and about 100° C., (c) between about 100° C. and about 200° C., (d) between about 200° C. and about 300° C., (e) between about 0° C. and about 200° C., or (f) between about 200° C. and about 400° C. during the heat treatment 240 step.

A wide variety of methods may be utilized to heat treat the semiconductor substrate 210. According to one embodiment, the heat treatment 240 step may be performed within a vacuum chamber at an elevated substrate temperature. In such embodiments, heat-treating may be performed under reduced pressure in the presence of an additive gas that can, for example, include hydrogen bromide (HBr), hydrogen (H₂), helium (He), argon (Ar), neon (Ne), xenon (Xe), nitrogen (N₂), and/or carbon monoxide (CO). In one example, the heat-treating may be performed using a substrate holder that acts as a hot-plate. Further, the heat-treating may be performed in the absence of plasma excitation, or by using plasma excitation of the additive gas and/or a high density plasma. In another example, the heat-treating may be performed by optical means such laser heating. Other methods for performing the polymerization shown in FIG. 2A can include, but are not limited to, using a hot filament above the substrate or using activation by e-beam, UV, EUV, High NA EUV, or Next Gen high NA/Hyper NA EUV.

A wide variety of metal precursors may be used during the plasma process 220 shown in FIG. 2A to form an EUV-active photoresist film. For example, a metal precursor comprising an EUV metal may be used. In the present disclosure, the term “EUV metal” may refer to a metal component with a high EUV absorption coefficient. According to one embodiment, the EUV metal may comprise tin (Sn). In other embodiments, the EUV metal may comprise zirconium (Zr), indium (In), antimony (Sb), bismuth (Bi), hafnium (Hf) or aluminum (Al). According to one embodiment, an organometallic oxide in the EUV-active photoresist film contains a central metal atom selected from the group consisting of tin (Sn), zirconium (Zr), indium (In), antimony (Sb), bismuth (Bi), zinc (Zn), hafnium (Hf), aluminum (Al) and combinations thereof. In the following description, various embodiments including figures are described using tin (Sn) as an exemplary metal component for the EUV-active photoresist film. It is recognized, however, that the metal component is not limited to tin (Sn) and other metals may also be present in the EUV-active photoresist film.

According to one embodiment, the metal precursor contains tin (Sn) and has the formula Sn_{α}O_{β} (O—CₘHₙ)ΓCₓH_{y}, where m, n, and α are arbitrary integers of 1 or more, β, Γ, x, and y are arbitrary integers of 0 or more, and β and Γ are not 0 at the same time. Examples include SnR1(O—R2)₃, SnR1₂(O—R2)₂, SnHR1(O—R2)₂, where R1: CH₃, C₂H₃, C₃H₅, C₄H₇, or C₆H₆, and R2: CH₃, C₂H₅, C₃H₇, or C₄H₉. Additional examples of a metal precursor containing tin (Sn) include SnCH₃^{t}Bu(O—^{t}Bu)₂, Sn^{t}Bu(O—^{t}Bu)₃, Sn^{t}Bu(O—C₃H₇)₃, Sn^{t}Bu(O—C₂H₅)₃, Sn^{t}Bu(O—CH₃)₃, SnCH₃C₂H₃(O—^{t}Bu)₂, and SnCH₃(C₂H₃)(O—CH₃)₂. Other examples of a metal precursor containing tin (Sn) include Sn(C₂H₄O₂) and Sn(OR)₂, where R may be selected from CH₃, C₂H₅ and C₄H₉. Still other examples include a mixture of Sn(N(CH₃)₂)₄ and HOCH₂CH₂OH.

According to another embodiment, the metal precursor contains tin (Sn) and has the formula SnₓC_{y}H_{z}, where x, y, and z are arbitrary integers of 1 or more. In one example, the metal precursor is selected from the group consisting of Sn(CH₃)₄, Sn(C₂H₅)₄, SnH(CH₃)₃, and SnH(C₂H₅)₃. In such an embodiment, the plasma-excited vapor 225 containing the metal precursor can further include an additive gas such as, but not limited to, hydrogen (H₂), helium (He), argon (Ar), neon (Ne), krypton (Kr), nitrogen (N₂) or acetylene (C₂H₂).

According to yet another embodiment, the metal precursor contains a metal (M) and has the formula M_{α}O_{β} (O—CₘHₙ)ΓCₓH_{y}, where m, n, and α are arbitrary integers of 1 or more, β, Γ, x, and y are arbitrary integers of 0 or more, and β and Γ are not 0 at the same time. Examples of metals (M) having a high EUV absorption coefficient include, but are not limited to, tin (Sn), zirconium (Zr), antimony (Sb), indium (In), bismuth (Bi), zinc (Zn), hafnium (Hf), and aluminum (Al).

In some embodiments, the plasma-excited vapor 225 may include a metal precursor and an additive precursor. For example, when the metal precursor contains tin (Sn) and has the formula Sn_{α}O_{β} (O—CₘHₙ)ΓCₓH_{y}, the additive precursor added to the plasma-excited vapor 225 may contain tin (Sn) and have a formula Sn_{α}CₓH_{y}, where m, n, and α are arbitrary integers of 1 or more. When the metal precursor contains a metal (M) and has the formula M_{α}O_{β} (O—CₘHₙ)ΓCₓH_{y}, the additive precursor added to the plasma-excited vapor 225 may contain a metal (M) and have a formula MαCxHy, where m, n, and α are arbitrary integers of 1 or more. In some embodiments, the plasma-excited vapor 225 may include a combination of precursors such as, for example, M_{α}O_{β} (O—CₘHₙ)ΓCₓH_{y}, M_{α}CₓH_{y}, and/or a nitrogen containing precursor, where M is a metal. In another embodiment, the additive precursor added to the plasma-excited vapor 225 may contain nitrogen (N₂) or an amine.

According to one embodiment, the photo-sensitivity of the EUV-active photoresist film to EUV radiation may be amplified with an additive monomer by introducing species with carbon-oxygen double bonds (C═O) that surround the organometallic oxide. According to one embodiment, the plasma-excited vapor 225 can further contain an additive monomer, such as for example, a hydrocarbon containing C═O bonds. For example, the plasma-excited vapor 225 can further contain an additive monomer, such as a ketone, an aldehyde, or an ester, each of which contains a carbonyl group with a carbon-oxygen double bond (C═O). The ketone may be selected from the group consisting of acetone, methyl ethyl ketone, methyl propyl ketone, and methyl isopropyl ketone. The aldehyde may be selected from the group consisting of formaldehyde, acetaldehyde, and propionaldehyde. The ester may be selected from the group consisting of ethyl methanoate, methyl acetate, ethyl acetate, methyl acrylate, methyl butanoate, and methyl salicylate.

According to one embodiment, the plasma-excited vapor 225 can include a metal precursor containing tin (Sn) and the additive monomer can contain a ketone, an aldehyde, or an ester. According to one embodiment, the plasma-excited vapor 225 can further include an additive gas such as, but not limited to, hydrogen (H₂), helium (He), argon (Ar), neon (Ne), xenon (Xe), nitrogen (N₂), carbon monoxide (CO), ammonia (NH₃), or hydrogen sulfide (H₂S).

FIG. 2B illustrates example chemistry that can be utilized for the chemical vapor polymer deposition and heat treatment steps shown in FIG. 2A, including an example metal precursor 227 that can be used in the plasma process 220 to form an example non-solid, organometallic oxide polymer layer 235 on the surface of the semiconductor substrate 210. In FIG. 2B, the metal precursor 227 is an organic tin compound comprising a carbon-carbon double bond 229. The plasma excitation of the organic tin compound affects the carbon-carbon double bond 229 to form the non-solid organometallic oxide polymer layer 235 on the surface of the semiconductor substrate 210. In some embodiments, the plasma excitation can include an additive gas, such as for example hydrogen (H₂), helium (He), argon (Ar), neon (Ne), krypton (Kr), nitrogen (N₂), acetylene (C₂H₂), or carbon monoxide (CO).

FIG. 2B schematically shows two alkoxide based metal precursor molecules that are plasma-excited, without the presence of an oxidizer such as, oxygen (O₂), ozone (O₃), water (H₂O), hydrogen peroxide (H₂O₂), carbon dioxide (CO₂) or carbon monoxide (CO), to form the non-solid organometallic oxide polymer layer 235 on the surface of the semiconductor substrate 210. The plasma-based reaction forms liquid-like oligomer units 237 of an organometallic oxide on the substrate surface. A subsequent heat-treating (such as thermal baking) may be used to further polymerize the liquid-like oligomer units 237 of the non-solid organometallic oxide polymer layer 235 to form the organometallic oxide polymer film 245. As schematically shown in FIG. 2B, for example, the liquid-like oligomer units 237 of the non-solid organometallic oxide polymer layer 235 polymerize, upon heat-treating, to form a photosensitive organometallic oxide polymer film 245 with polymerized carbon-carbon bonds.

The chemical vapor polymerization (CVP) shown in FIGS. 2A and 2B, namely plasma excitation of the organic tin compound followed by the heat-treating of the semiconductor substrate, forms an organometallic oxide with polymerized carbon-carbon bonds, which increases the mechanical strength and photosensitivity of the EUV-active photoresist film.

In the example chemistry shown in FIG. 2B, the organic tin compound contains an Sn—O— unit that is protected by CₘHₙ ligands (e.g., methane (CH₃) and ethyl radicals (C₂H₅)). The CₘHₙ ligands create carbon-carbon bondings to improve film stability and strength. The CmHn ligands also prevent Sn—O—Sn bondings in a given polymerized molecule from bonding with other Sn—O—Sn bondings in other polymerized molecules in the subsequently formed film. In another aspect, the CₘHₙ ligands promote solubility of portions of the EUV-active photoresist to be removed during a subsequently performed development step (for example, in the area of non EUV exposure). Further, organic tin compounds containing carbon-carbon double bonds 229 enhance polymerization during the heat treatment 240 step to form an organometallic oxide polymer film 245 with a polymerized carbon-carbon backbone 246 to increase the mechanical strength and photo-sensitivity of the EUV-active photoresist film. In some embodiments, the photo-sensitivity of the EUV-active photoresist film may be increased by adding a monomer to the plasma-excited vapor 225 (not shown in FIG. 2B), wherein the additive monomer has carbon-oxygen double bonds (C═O) that surround the organometallic oxide.

FIG. 3A illustrates one embodiment of a process flow 300 used to pattern and develop an EUV-active photoresist film, such as the EUV-active photoresist film formed in FIG. 2A. FIG. 3B schematically shows example reactions that may occur during the EUV lithography process and (optional) heat treating step shown in FIG. 3A.

As shown in FIG. 3A, an EUV lithography process may be performed by exposing the surface of the semiconductor substrate 210 containing the EUV-active photoresist film (i.e., the organometallic oxide polymer film 245) to EUV radiation 255 (e.g., at a wavelength of 13.5 nm) in an EUV exposure 250 step. The EUV lithography process may utilize a photomask (not shown) such that a photo-induced reaction occurs only in regions 247 of the EUV-active photoresist exposed to the EUV radiation 255. The regions 247 of the EUV-active photoresist exposed to the EUV radiation 255 are converted to a reacted photoresist. Regions 249 of the EUV-active photoresist not exposed to the EUV radiation 255 remain unreacted. After the EUV exposure 250 step, an optional heat-treating step (for example, post-exposure bake (PEB)) 260 may be performed to stabilize the photoresist after EUV exposure by completing the reactions initiated during exposure and promote —(Sn—O-)n cross bonding in the EUV exposed area. In some embodiments, the optional heat-treating step 260 may prevent changes in line edge roughness (LER), line width roughness (LWR) and/or critical dimension (CD).

After completing the EUV exposure 250 and the optional post-exposure bake (PEB) 260, a developing step 270 may be performed to remove a portion of the EUV-active photoresist for patterning, thereby providing a patterned photoresist 275 on the substrate surface. The developing step 270 may be a wet or dry process. Conventionally, a portion of the EUV-active photoresist may be removed by treating the substrate with a developing solution to dissolve the reacted (in case of a positive tone resist) or unreacted (in case of a negative tone resist) regions of the EUV-active photoresist. A similar wet process may be applied in various embodiments. Alternately, a dry process may be used to remove the reacted or unreacted regions of the EUV-active photoresist in other embodiments. The dry process may comprise, for example, a selective plasma etch process or a thermal process, advantageously eliminating the use of a developing solution. In certain embodiments, the dry process may be performed using reactive ion etching (RIE) process or atomic layer etching (ALE).

FIG. 3B shows potential reactions that may occur during the EUV exposure 250 optional heat-treating step (post-exposure bake (PEB)) 260 steps shown in FIG. 3A. As shown in FIG. 3B, a first reaction 257 may occur during the EUV exposure 250 to form metal (for example, tin) alkoxide oligomers. During the EUV exposure 250 step, tin (Sn) atoms absorb EUV photons and expose secondary electrons to surrounding —C bondings to break Sn—C, O—C bonds, thus forming Sn—H and Sn—OH bonds, as shown in FIG. 3B. During the optional PEB 260, the converted Sn—H and Sn—OH bonds form a larger network of stable Sn—O—Sn bonds in a second reaction 265.

The EUV-active photoresist disclosed herein provides various advantages over conventional photoresists used for EUV lithography. For example, the EUV-active photoresist formed in the process flow 200 shown in FIG. 2A has a higher EUV absorbance, and thereby better resist sensitivity, compared to conventional chemically amplified resists (CARs). In some embodiments, the higher EUV absorbance may enable the thickness of the photoresist required for an acceptable performance to be decreased. The EUV-active photoresist disclosed herein may also advantageously exhibit an etch resistance that is better than conventional CARs. In addition, the methods used herein to create the EUV-active photoresist may provide the photoresist with a uniform chemical composition, which may be beneficial in mitigating issues of blur or line edge roughness.

Further, the EUV-active photoresist disclosed herein may be formed over a substrate and developed by dry or wet processes. While conventional techniques used to apply and develop CARs are based on wet processes, dry processes for the formation and developing of the EUV-active photoresist disclosed herein provide better process control at the nanoscale than a wet process (e.g., when forming features that are a few nanometers or sub-nanometer in critical dimension). Although dry processes are preferred, conventional spin-on processes for deposition and wet processes using developing solutions are also available for the methods of this disclosure.

In addition to CARs, the EUV-active photoresist disclosed herein provides various advantages over conventional vapor-deposited metal oxide-containing films, such as those described in the '004 Patent. Unlike the conventional processes disclosed in the '004 Patent, which react various organotin oxide precursors with an oxidizer (for example, carbon dioxide or carbon monoxide) in a typical CVD/ALD process to form a solid metal oxide-containing film on the semiconductor substrate, the improved process flows and methods disclosed herein use a low temperature, low ion energy plasma process, which exposes the substrate surface to a plasma-excited vapor comprising a metal precursor having carbon-carbon double bonds to deposit a non-solid, organometallic oxide polymer layer (containing liquid-like oligomer units) having carbon-carbon bonds onto the substrate surface. The carbon-carbon double bonds provided within the metal precursor enhance polymerization during the subsequently performed heat treatment step to form the organometallic oxide polymer film with carbon-carbon bonds. The presence of carbon-carbon bonds in the organometallic oxide polymer film increases the mechanical strength and stability of the EUV-active photoresist disclosed herein compared to conventional vapor-deposited metal oxide-containing films containing Sn—OH and Sn—O—Sn bonds.

### Methods for Filling Gaps Within a Patterned Layer

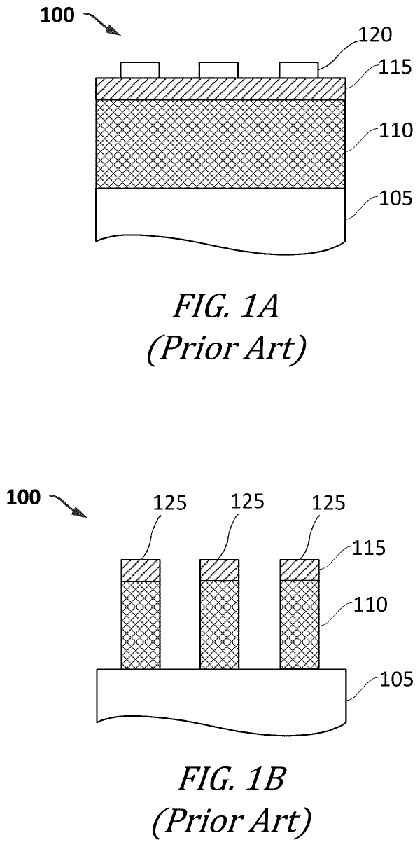

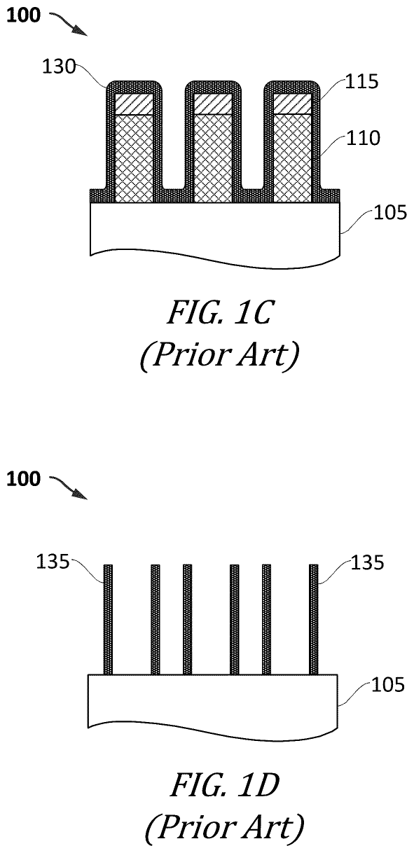

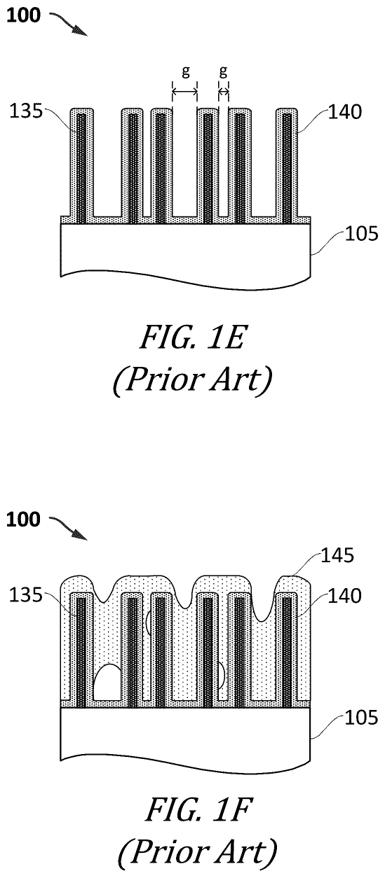

As noted above in the Background Section, incomplete filling may occur when spin-on materials (such as, e.g., spin-on glass (SOG), spin-on carbon (SOC) or other spin-on materials) are used to fill narrow gaps within a patterned layer. For example, voids or bubbles may be created within the gap fill material 145 when spin-on materials are used to fill the gaps shown in FIG. 1F.

In addition to forming EUV-active photoresists, the techniques disclosed herein can be used, in some embodiments, to provide new gap fill materials and methods for filling narrow gaps within a patterned layer provided on a semiconductor substrate.

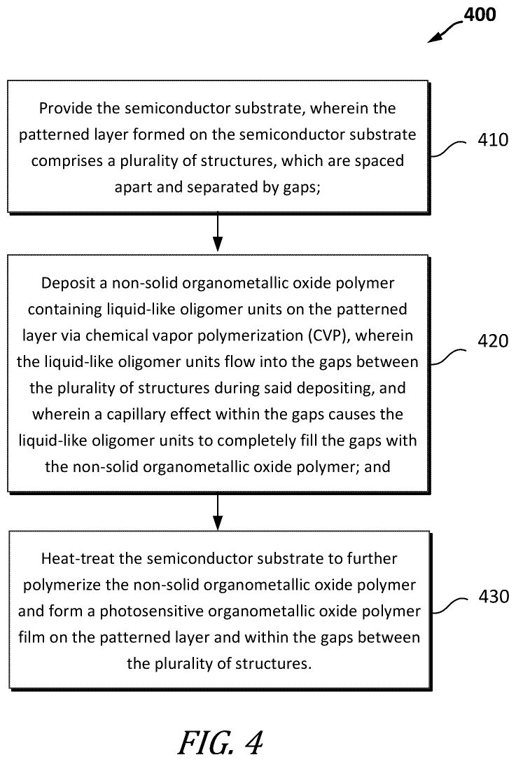

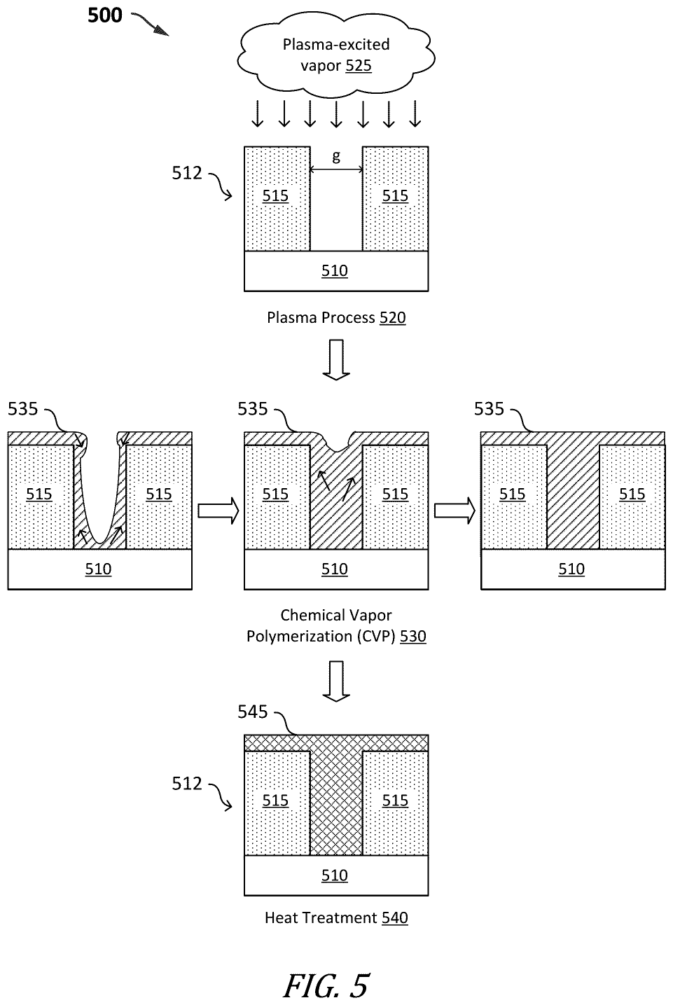

FIG. 4 illustrates one embodiment of a method 400 that utilizes the techniques disclosed herein to fill gaps within a patterned layer formed on a semiconductor substrate. FIG. 5 illustrates an example process flow 500 that uses the method 400 to fill at least one gap within a patterned layer with a photosensitive organometallic oxide polymer film. It will be recognized that the embodiments shown in FIGS. 4-5 are merely exemplary and additional methods and process flows may utilize the techniques described herein. Further, additional processing steps may be added to the method and process flow shown in the FIGS. 4-5 as the steps described are not intended to be exclusive. Moreover, the order of the steps is not limited to the order shown in the figures as different orders may occur and/or various steps may be performed in combination or at the same time.

As shown in FIGS. 4-5, the method 400 and process flow 500 may generally begin by providing a semiconductor substrate 510 having a patterned layer 512 formed thereon (in step 410). The patterned layer 512 formed on the semiconductor substrate 510 may include a plurality of structures 515, which are spaced apart and separated by gaps. Although the example process flow 500 shown in FIG. 5 illustrates only one gap (g) formed between a pair of structures 515, it is recognized that the patterned layer 512 may include substantially any number of structures 515, which are spaced apart and separated by gaps (g). It is further recognized that the width of the gaps separating the structures 515 may be substantially the same across the patterned layer 512, or may be different, depending on the configuration of the patterned layer 512.

The method 400 further includes depositing a non-solid organometallic oxide polymer 535 containing liquid-like oligomer units on the patterned layer 512 via chemical vapor polymerization (in step 420). The non-solid organometallic oxide polymer 535 is preferably deposited in step 420 by performing a low temperature, low ion energy plasma process 520 that exposes the semiconductor substrate 510 to a plasma-excited vapor 525 comprising a metal precursor having carbon-carbon double bonds. In some embodiments, an additive precursor may also be included within the plasma-excited vapor 525. Examples of suitable metal precursors and additive precursors are discussed in more detail below.

The low temperature, low ion energy plasma process 520 performed in step 420 may be similar to the plasma process 220 shown in FIG. 2A and described above. During the plasma deposition step 420, the semiconductor substrate 510 is maintained at a relatively low substrate temperature (e.g., a substrate temperature less than about 150° C., and more specifically, between about −50° C. and about 0° C.), while ions within the plasma-excited vapor 525 are maintained at a relatively low ion energy (e.g., an ion energy less than about 50 eV, and more specifically, between about 0 eV and about 5 eV).

When exposed to a plasma-excited vapor comprising a metal precursor having carbon-carbon double bonds under low temperature, low ion energy conditions, a non-solid organometallic oxide polymer 535 containing liquid-like oligomer units is deposited on the patterned layer 512 and within the gaps (g) between the plurality of structures 515 via chemical vapor polymerization (CVP) 530. The liquid-like oligomer units within the non-solid organometallic oxide polymer 535 flow into the gaps (g) between the plurality of structures 515. A capillary effect within the gaps (g) causes the liquid-like oligomer units to completely fill the gaps with the non-solid organometallic oxide polymer 535 as shown, for example, in FIG. 5.

After forming the non-solid organometallic oxide polymer 535 on the patterned layer 512 and within the gaps (g) between the plurality of structures 515, the semiconductor substrate 510 is subjected to a heat treatment 540 (in step 430) to further polymerize the non-solid organometallic oxide polymer 535 and form a photosensitive organometallic oxide polymer film 545 having carbon-carbon bonds on the patterned layer 512 and within the gaps (g) between the plurality of structures 515. Depending on the metal precursor used during the plasma deposition step 420, the photosensitive organometallic oxide polymer film 545 formed in step 430 may contain a central metal atom of tin (Sn), zirconium (Zr), indium (In), antimony (Sb), bismuth (Bi), zinc (Zn), hafnium (Hf), or aluminum (Al), or combinations thereof.

A wide variety of methods may be utilized to heat-treat the semiconductor substrate 510 (in step 430) as discussed above in reference to FIG. 2A. During the heat treatment 540 (step 430), the semiconductor substrate 510 is heated to a substrate temperature, which is greater than the substrate temperature used during the low temperature, low ion energy plasma process 520. According to one embodiment, the semiconductor substrate 510 is heated to a substrate temperature between about 0° C. and about 400° C. during the heat treatment 540 (step 430). For example, the semiconductor substrate 510 can be heated to, and maintained at, a substrate temperature: (a) between about 0° C. and about 50° C., (b) between about 50° C. and about 100° C., (c) between about 100° C. and about 200° C., (d) between about 200° C. and about 300° C., (e) between about 0° C. and about 200° C., or (f) between about 200° C. and about 400° C. during the heat treatment 540 step. During heat treatment, the liquid-like oligomer units having carbon-carbon bonds polymerize to form the photosensitive organometallic oxide polymer film 545 with polymerized carbon-carbon bonds.

A wide variety of metal precursors may be utilized within the method 400 and process flow 500 shown in FIGS. 4-5. The metal precursor may include a metal alkoxide. In some embodiments, the metal precursor may contain tin (Sn). For example, the metal precursor may have the formula Sn_{α}O_{β} (O—CₘHₙ)ΓCₓH_{y}, where m, n, and α are arbitrary integers of 1 or more, β, Γ, x, and y are arbitrary integers of 0 or more, and β and Γ are not 0 at the same time. In one example, the metal precursor may include SnR1(O—R2)₃, SnR1₂(O—R2)₂, or SnHR1(O—R2)₂, where R1: CH₃, C₂H₃, C₃H₅, C₄H₇, or C₆H₆, and R2: CH₃, C₂H₅, C₃H₇, or C₄H₉. In another example, the metal precursor may include SnCH₃^{t}Bu(O—^{t}Bu)₂, Sn^{t}Bu(O—^{t}Bu)₃, Sn^{t}Bu(O—C₃H₇)₃, Sn^{t}Bu(O—C₂H₅)₃, Sn^{t}Bu(O—CH₃)₃, SnCH₃C₂H₃(O—^{t}Bu)₂, or SnCH₃(C₂H₃)(O—CH₃)₂. Other examples of a metal precursor containing tin (Sn) include Sn(C₂H₄O₂) and Sn(OR)₂, where R may be selected from CH₃, C₂H₅ and C₄H₉. Still other examples include a mixture of Sn(N(CH₃)₂)₄ and HOCH₂CH₂OH.

In other embodiments, the metal precursor contains tin (Sn) and has the formula SnₓC_{y}H_{z}, where x, y, and z are arbitrary integers of 1 or more. For example, the metal precursor may be selected from the group consisting of Sn(CH₃)₄, Sn(C₂H₅)₄, SnH(CH₃)₃, and SnH(C₂H₅)₃. In such an embodiment, the plasma-excited vapor 525 containing the metal precursor can further include an additive gas such as, but not limited to, hydrogen (H₂), helium (He), argon (Ar), neon (Ne), krypton (Kr), nitrogen (N₂) or acetylene (C₂H₂).

In further embodiments, the metal precursor contains a metal (M) and has the formula M_{α}O_{β} (O—CₘHₙ)ΓCₓH_{y}, where m, n, and α are arbitrary integers of 1 or more, β, Γ, x, and y are arbitrary integers of 0 or more, and β and Γ are not 0 at the same time. Examples of metals (M) having a high EUV absorption coefficient include, but are not limited to, tin (Sn), zirconium (Zr), antimony (Sb), indium (In), bismuth (Bi), zinc (Zn), hafnium (Hf), and aluminum (Al).

In some embodiments, the plasma-excited vapor 525 may include a metal precursor and an additive precursor. For example, when the metal precursor contains tin (Sn) and has the formula Sn_{α}O_{β} (O—CₘHₙ)ΓCₓH_{y}, the additive precursor added to the plasma-excited vapor 525 may contain tin (Sn) and have a formula Sn_{α}CₓH_{y}, where m, n, and α are arbitrary integers of 1 or more. When the metal precursor contains a metal (M) and has the formula M_{α}O_{β} (O—CₘHₙ)ΓCₓH_{y}, the additive precursor added to the plasma-excited vapor 525 may contain a metal (M) and have a formula M_{α}CₓH_{y}, where m, n, and α are arbitrary integers of 1 or more. In some embodiments, the plasma-excited vapor 525 may include a combination of precursors such as, for example, M_{α}O_{β} (O—CₘHₙ)ΓCₓH_{y}, M_{α}CₓH_{y}, and/or a nitrogen containing precursor, where M is a metal. In another embodiment, the additive precursor added to the plasma-excited vapor 525 may contain nitrogen (N₂) or an amine.

In some embodiments, the plasma-excited vapor 525 may further include an additive monomer to increase a photo-sensitivity of the photosensitive organometallic oxide polymer film 545 to EUV radiation. In some embodiments, the additive monomer may include a hydrocarbon containing carbon-oxygen double bonds. For example, the additive monomer may include a ketone, an aldehyde, or an ester.

In some embodiments, the step of exposing the surface of the semiconductor substrate to the plasma-excited vapor 525 may be performed at relatively low ion energies (e.g., less than 50 eV, and more specifically, between about 0 eV and about 5 eV) and relatively low substrate temperatures (e.g., less than about 150° C., and more specifically, between about −50° C. and about 0° C.). In such embodiments, the non-solid organometallic oxide polymer 535 formed on the patterned layer 512 and within the gaps (g) between the plurality of structures 515 may include liquid-like oligomer units having carbon-carbon bonds.

In some embodiments, the step of exposing the surface of the semiconductor substrate to the plasma-excited vapor 525 may be performed at relatively high reactive power. When using an organometal precursor of saturated hydrocarbon ligands such as, for example Sn_{α}O_{β} (O—CₘHₙ)ΓCₓH_{y}, (where y=2x+1), reducing the hydrogen partial pressure in the plasma-excited vapor 525 enhances polymerization of the carbon-carbon (C—C) bonds to form the organic film. The reactivity of the plasma-excited vapor 525 is controlled by the RF power. Precursor molecules of Sn_{α}O_{β} (O—CₘHₙ)ΓCₓH_{y} break with high reactive plasma-excited vapor, creating Sn—O—Sn bonds in the photoresist polymer with C—C bonds. The ratio of (—Sn—O—Sn—)/(—C—C—) improves stability and mechanical strength of the organic resist film.

The processes and methods disclosed herein provide various advantages over conventional gap fill materials and methods for filling narrow gaps within a patterned layer provided on a semiconductor substrate. Unlike conventional methods that utilize spin-on materials, the processes and methods disclosed herein utilize a low temperature, low ion energy plasma process 520 to form a non-solid, organometallic oxide polymer 535 on the patterned layer 512 that completely fills the gaps (g) between the plurality of structures 515. Upon subsequent heat treatment, the non-solid, organometallic oxide polymer 535 deposited on the patterned layer 512 and within the gaps (g) is further polymerized to form a photosensitive organometallic oxide polymer film 545 with improved photosensitivity, mechanical strength and stability compared to conventional photoresist materials.

In some embodiments, the photosensitive organometallic oxide polymer film 545 can be selectively exposed to EUV radiation and selectively etched to create features (such as, e.g., holes, trenches, etc.) within the patterned layer 512. As noted above, exposing the photosensitive organometallic oxide polymer film 545 to EUV radiation induce changes in material properties of the polymer film. During EUV exposure, the metal atoms (e.g., tin (Sn) atoms) in the photosensitive organometallic oxide polymer film 545 absorb EUV photons and expose secondary electrons to surrounding —C bondings to break Sn—C and O—C bonds, thus forming Sn—H and Sn—OH bonds, as shown in the example provided in FIG. 3B. In some embodiments, the photosensitive organometallic oxide polymer film 545 may be exposed to an optional heat treatment (e.g., a post exposure bake (PEB)) after EUV exposure to induce a second reaction within the polymer film that causes the converted Sn—H and Sn—OH bonds to form a larger network of stable Sn—O—Sn bonds.

In some embodiments, the material changes induced within photosensitive organometallic oxide polymer film 545 after EUV exposure (and optional PEB) may enable portions of the photosensitive organometallic oxide polymer film 545 to be selectively removed during subsequent processing steps. In some embodiments, the photosensitive organometallic oxide polymer film 545 may be selectively exposed to EUV radiation to change an etch selectivity of a portion of the photosensitive organometallic oxide polymer film 545 formed within one or more of the gaps. After EUV exposure (and optional PEB), the photosensitive organometallic oxide polymer film 545 can be selectively etched to remove the portion of the photosensitive organometallic oxide polymer film 545 from the one or more of the gaps to create one or more features (such as, e.g., holes, trenches, etc.) within the patterned layer 512.

### Methods to Improve Contact Hole Patterning in a SAMP Process

As feature scale size and pitch shrink in self-aligned multiple patterning (SAMP) processes, new gap fill materials are needed to increase etch selectivity and improve contact hole patterning. In some embodiments, the techniques disclosed herein can be used to improve contact hole patterning in a SAMP process flow. For example, the low temperature, low ion energy plasma process disclosed herein can be used to deposit liquid-like oligomer units on a patterned layer and within the gaps between the plurality of structures (e.g., the mandrels, spacers, etc.) formed during the SAMP process flow. The liquid-like oligomer units deposited on and within the patterned layer are photosensitive and offer excellent gap fill properties, especially in the narrow gaps formed during the SAMP process flow. Subsequent heat treatment further polymerizes the liquid-like oligomer units to form a new organometallic compound (e.g., a photosensitive organometallic oxide polymer film) in the SAMP process flow. Upon EUV exposure, the material properties of the photosensitive organometallic oxide polymer film can be tuned to change the etch selectivity within select portions of the photosensitive organometallic oxide polymer film and enable grid patterning.

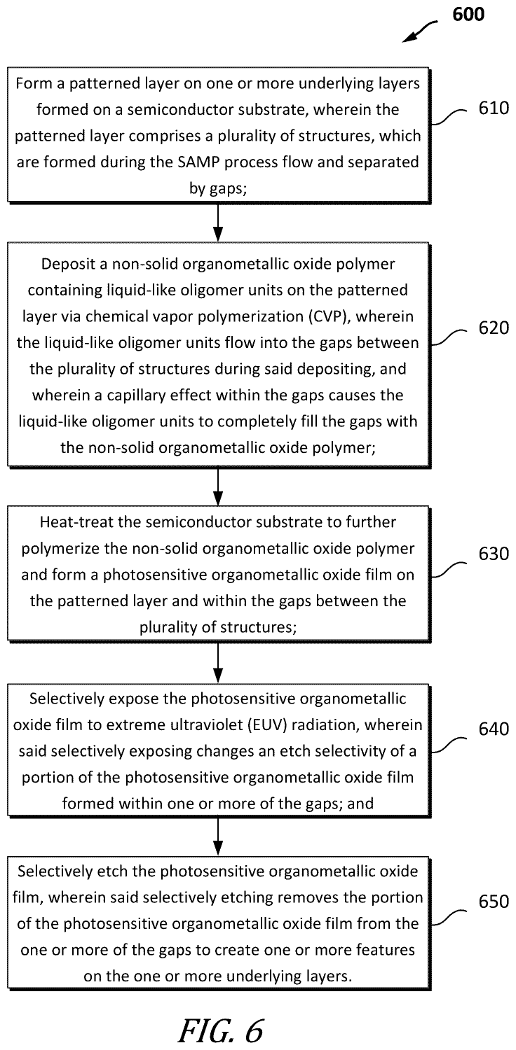

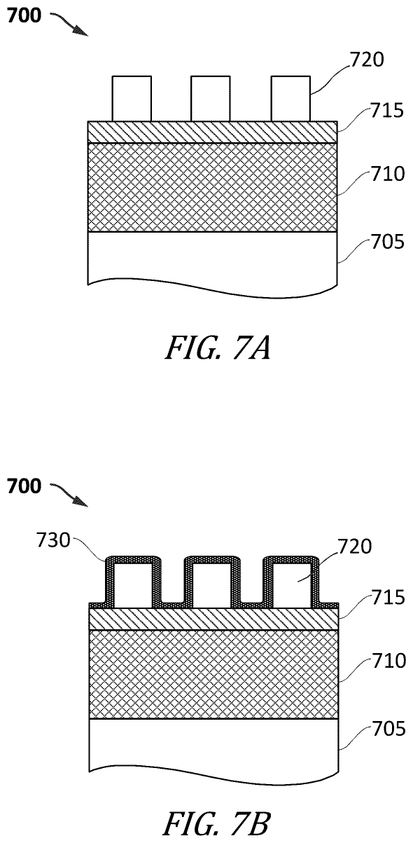

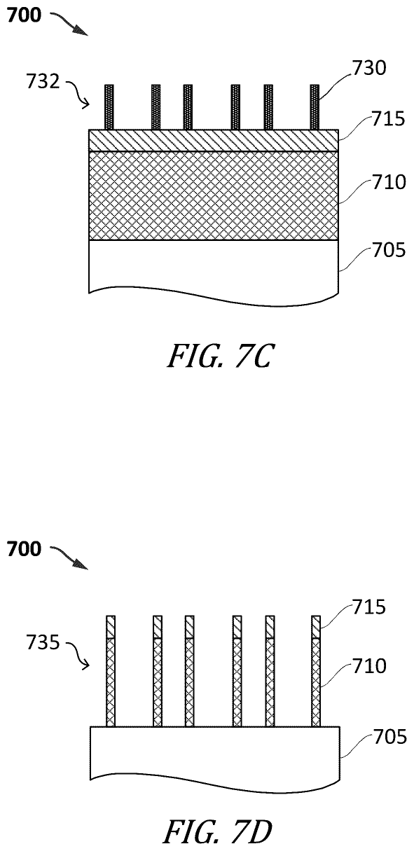

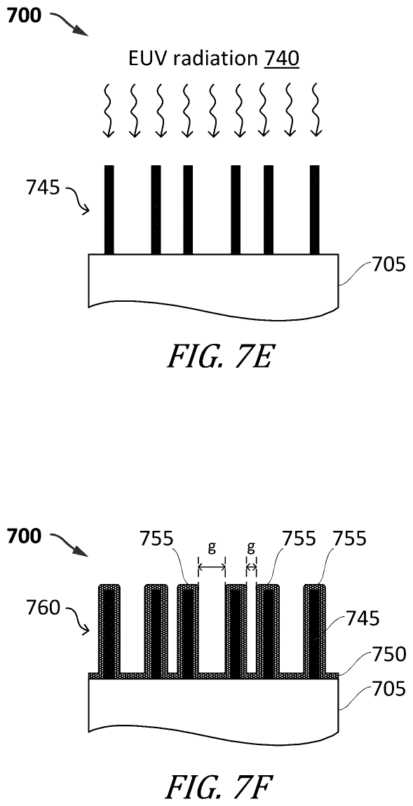

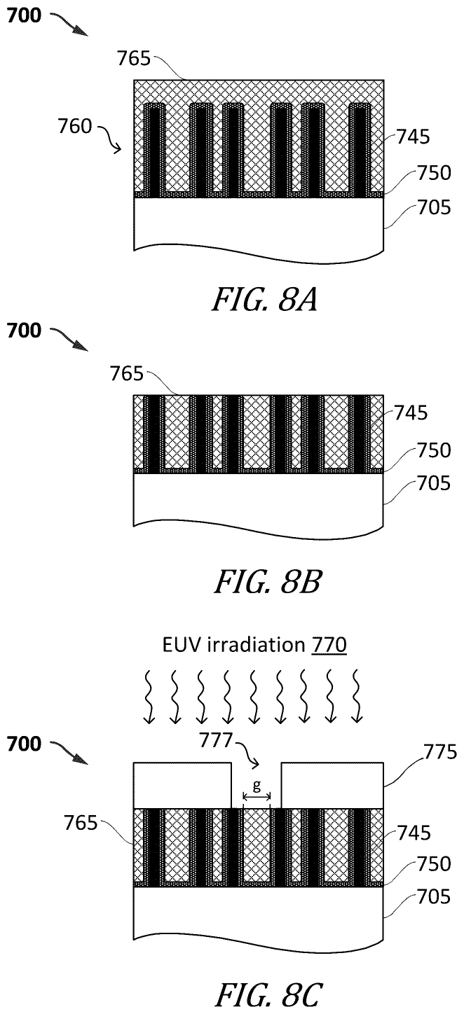

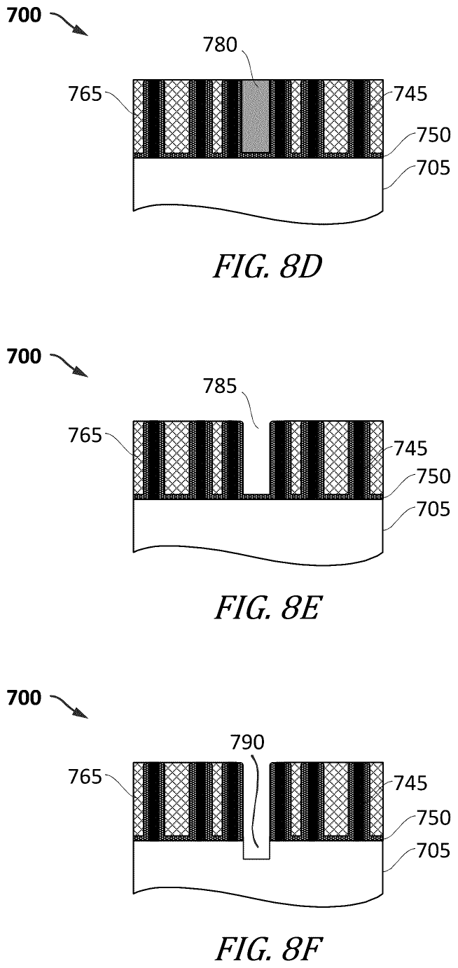

FIG. 6 illustrates one embodiment of a method 600 that uses the techniques disclosed herein in a self-aligned multi-patterning (SAMP) process flow. FIGS. 7-8 illustrate example process flows that use the method 600 shown in FIG. 6 to form contact holes in a SAMP process flow. It will be recognized that the embodiments shown in FIGS. 6-8 are merely exemplary and additional methods and process flows may utilize the techniques described herein. Further, additional processing steps may be added to the method and process flow shown in the FIGS. 6-8 as the steps described are not intended to be exclusive. Moreover, the order of the steps is not limited to the order shown in the figures as different orders may occur and/or various steps may be performed in combination or at the same time.

The method 600 shown in FIG. 6 may generally begin by forming a patterned layer on one or more underlying layers form on a semiconductor substrate (in step 610). The patterned layer includes a plurality of structures (e.g., mandrels, spacers, etc.), which are formed during the SAMP process flow and separated by gaps. In some embodiments, a SAMP process flow as shown in FIGS. 7A-7F can be used to form the patterned layer on the semiconductor substrate (in step 610). It is recognized, however, that other SAMP process flows can be used to form the patterned layer. For example, the SAMP process flow shown in FIGS. 1A-1E can be used.

FIGS. 7A-7F illustrate one example of a self-aligned double patterning (SADP) process flow that can be used to form a patterned layer on a substrate (in step 610). As shown in FIG. 7A, a substrate 700 is provided with a core material layer 710 formed above one or more underlying layers 705 (e.g., various patterned and unpatterned layers formed during substrate processing). The core material layer 710 may include a wide variety of materials. In some embodiments, the core material layer 710 may include an oxide, nitride, carbon, amorphous silicon or a metallic material. For example, the core material layer 710 may be a silicon nitride (SiN) layer. In other embodiments, the core material layer 710 may include a photosensitive organometallic oxide polymer film, as shown in various figures and described herein.

As shown in FIG. 7A, the substrate 700 further includes a photoresist pattern 720 formed above the core material layer 710. The photoresist pattern 720 may include a wide range of photoresist materials. In one example embodiment, the photoresist pattern 720 may include an EUV-active photoresist as shown in various figures and described herein. In some embodiments, an adhesion layer 715 may be provided between the photoresist pattern 720 and the core material layer 710 to improve the adhesion there between.

In the embodiment shown in FIG. 7A, the photoresist pattern 720 forms the mandrels used in the SADP process flow. After forming a spacer deposition layer 730 over the substrate 700, as shown in FIG. 7B, the substrate 700 is subjected to a mandrel pull process (e.g., a first plasma etch process) to remove the photoresist pattern 720 (i.e., the mandrels), but leave portions of the spacer deposition layer 730 that were deposited on the sidewall surfaces of the photoresist pattern 720, to form the spacers 732 shown in FIG. 7C. In some embodiments, the mandrel pull process used to form the spacers 732 may continue to remove portions of the adhesion layer 715 and the core material layer 710 not covered by the spacers 732, thereby forming spacers 735, as shown in FIG. 7D. Alternatively, a second plasma etch process may be used to remove the uncovered portions of the adhesion layer 715 and the core material layer 710 to form the spacers 735.

In some embodiments, the substrate 700 may be exposed to EUV radiation 740, as shown in FIG. 7E. For example, when the core material layer 710 comprises a photosensitive organometallic oxide polymer film, the substrate 700 may be exposed to EUV radiation 740 to induce material changes in the photosensitive organometallic oxide polymer film that change an etch selectivity of the polymer film. In doing so, the optional EUV exposure step may be used to form spacers 745 having different etch characteristics than the spacers 735.

In some embodiments, a second spacer deposition layer 750 may be deposited over the substrate 700, as shown in FIG. 7F, to form a patterned layer 760 having a plurality of spacers 755, which are spaced apart and separated by gaps (g). The width of the gaps (g) separating the spacers 755 may be substantially the same across the patterned layer 760, or may be different as shown in FIG. 7F, depending on the configuration of the patterned layer. However, the width of the gaps (g) and the spacer pitch may generally be small. In one example embodiment, the width of the gaps may be less than 20 nm and the spacer pitch may be 28 nm or less. Due to the small gap width, new gap fill materials and methods are needed to completely fill the gaps.

FIGS. 8A-8E illustrate an example process flow that utilizes the method 600 shown in FIG. 6 to fill the gaps (g) with a photosensitive organometallic oxide polymer film 765 and create contact holes within the patterned layer 760 formed in FIG. 7F. It is recognized that the method 600 shown in FIG. 6 and the process flow shown in FIGS. 8A-8E can also be used to fill gaps and create contact holes within other patterned layers, such as but not limited to, the patterned layer shown in FIG. 1E.

After forming a patterned layer 760 on a semiconductor substrate (in step 610), as shown for example in FIGS. 7A-7F, the method 600 may deposit a non-solid organometallic oxide polymer containing liquid-like oligomer units on the patterned layer 760 via chemical vapor polymerization (in step 620). The non-solid organometallic oxide polymer is preferably deposited in step 620 by performing a low temperature, low ion energy plasma process that exposes the semiconductor substrate 700 to a plasma-excited vapor comprising a metal precursor having carbon-carbon double bonds. In some embodiments, an additive precursor may also be included within the plasma-excited vapor. Examples of suitable metal precursors and additive precursors are discussed in more detail above in reference to FIGS. 2-5.

The low temperature, low ion energy plasma process performed in step 620 may be similar to the plasma process 520 shown in FIG. 5 and described above. During the plasma deposition step 620, the semiconductor substrate 700 is maintained at a relatively low substrate temperature (e.g., a substrate temperature less than about 150° C., and more specifically, between about −50° C. and about 0° C.), while ions within the plasma-excited vapor are maintained at a relatively low ion energy (e.g., an ion energy less than about 50 eV, and more specifically, between about 0 eV and about 5 eV).

When exposed to a plasma-excited vapor comprising a metal precursor having carbon-carbon double bonds under low temperature, low ion energy conditions, a non-solid organometallic oxide polymer containing liquid-like oligomer units is deposited on the patterned layer 760 and within the gaps (g) between the plurality of structures (e.g., spacers 755) via chemical vapor polymerization (CVP). The liquid-like oligomer units within the non-solid organometallic oxide polymer flow into the gaps (g) between the plurality of structures. A capillary effect within the gaps (g) causes the liquid-like oligomer units to completely fill the gaps with the non-solid organometallic oxide polymer as shown, for example, in FIG. 5.

Once the non-solid organometallic oxide polymer is deposited on the patterned layer 760 and within the gaps (g) between the plurality of structures (e.g., spacers 755), the semiconductor substrate 700 is subjected to a heat treatment (in step 630) to further polymerize the non-solid organometallic oxide polymer and form a photosensitive organometallic oxide polymer film 765 having carbon-carbon bonds on the patterned layer 760 and within the gaps (g) between the plurality of structures, as shown for example in FIG. 8A. Depending on the metal precursor used during the plasma deposition step 620, the photosensitive organometallic oxide polymer film 765 formed in step 630 may contain a central metal atom of tin (Sn), zirconium (Zr), indium (In), antimony (Sb), bismuth (Bi), zinc (Zn), hafnium (Hf), or aluminum (Al), or combinations thereof.

A wide variety of methods may be utilized to heat-treat the semiconductor substrate 700 (in step 630) as discussed above in reference to FIG. 2A. During the heat treatment step, the semiconductor substrate 700 is heated to a substrate temperature, which is greater than the substrate temperature used during the low temperature, low ion energy plasma process performed in step 620. According to one embodiment, the semiconductor substrate 700 may be heated to a substrate temperature between about 0° C. and about 400° C. during the heat treatment step. For example, the semiconductor substrate 700 can be heated to, and maintained at, a substrate temperature: (a) between about 0° C. and about 50° C., (b) between about 50° C. and about 100° C., (c) between about 100° C. and about 200° C., (d) between about 200° C. and about 300° C., (e) between about 0° C. and about 200° C., or (f) between about 200° C. and about 400° C. during the heat treatment step. During heat treatment, the liquid-like oligomer units having carbon-carbon bonds polymerize to form the photosensitive organometallic oxide polymer film 765 with polymerized carbon-carbon bonds, as shown in FIG. 8A.

Unlike conventional processing methods that utilize spin-on materials, the low temperature, low ion energy plasma process and subsequent heat treatment described above can be used to form a photosensitive organometallic oxide polymer film 765 on a patterned layer 760 in a manner that completely fills the gaps (g) within the patterned layer. In addition to excellent gap fill properties, the photosensitive organometallic oxide polymer film 765 can be exposed to EUV light to change the etch selectivity of the polymer film and enable grid patterning.

After forming the photosensitive organometallic oxide polymer film 765 on the patterned layer 760 and within the gaps (g) between the plurality of structures (e.g., spacers 755), the method 600 may selectively expose the photosensitive organometallic oxide polymer film 765 to EUV radiation 770 to change an etch selectivity of a portion of the photosensitive organometallic oxide polymer film 765 formed within one or more of the gaps (in step 640). After EUV exposure, the photosensitive organometallic oxide polymer film 765 may be selectively etched to remove the portion of the photosensitive organometallic oxide polymer film 765 from the one or more of the gaps to create one or more features (such as, e.g., holes, trenches, etc.) on the one or more underlying layers 705 (in step 650).

FIGS. 8B-8F illustrate one way in which the photosensitive organometallic oxide polymer film 765 can be selectively exposed to EUV radiation 770 and selectively etched to create more contact holes within the patterned layer 760. For example, an etch back or chemical mechanical polishing (CMP) process may be performed on the semiconductor substrate 700 to planarize or remove portions of the photosensitive organometallic oxide polymer film 765 formed above the patterned layer 760, as shown in FIG. 8B. After planarization, a patterned photoresist 775 may be formed above the planarized surface, as shown in FIG. 8C. The patterned photoresist 775 may have one or more openings 777 that selectively expose the photosensitive organometallic oxide polymer film 765 formed within one or more of the gaps to the EUV radiation 770.

When a SADP process flow as shown in FIGS. 7A-7F is used to form the patterned layer 760, the width of the openings 777 may be larger than the width of the gaps (g). In other words, the use of a photosensitive organometallic oxide polymer film within the core material layer 710 and the subsequent EUV exposure step shown in FIG. 7E may reduce the photolithography requirements needed to form the one or more openings 777 in the patterned photoresist 775. In other embodiments, the width of the opening(s) 777 may be substantially equal to the width of the gaps (g) when other core materials are used.

As shown in FIG. 8D, the EUV radiation 770 induces material changes within the exposed portion 780 of the photosensitive organometallic oxide polymer film 765 underlying the one or more openings 777. During EUV exposure, the metal atoms (e.g., tin (Sn) atoms) in the exposed portion 780 of the photosensitive organometallic oxide polymer film 765 absorb EUV photons and expose secondary electrons to surrounding —C bondings to break Sn—C and O—C bonds, thus forming Sn—H and Sn—OH bonds, as shown in the example provided in FIG. 3B. In some embodiments, the photosensitive organometallic oxide polymer film 765 may be exposed to an optional heat treatment (e.g., a post exposure bake (PEB)) after EUV exposure to induce a second reaction that causes the converted Sn—H and Sn—OH bonds to form a larger network of stable Sn—O—Sn bonds. The material changes induced within the exposed portion 780 of the photosensitive organometallic oxide polymer film 765 after EUV exposure (and optional PEB) enable the exposed portion 780 of the photosensitive organometallic oxide polymer film 765 to be selectively removed during subsequent processing steps.

In some embodiments, the method 600 may selectively etch the photosensitive organometallic oxide polymer film 765 (in step 650) by removing the exposed portion 780 of the photosensitive organometallic oxide polymer film 765 from the one or more of the gaps to create one or more features 785 on the one or more underlying layers 705, as shown in FIG. 8E. A wet or dry etch process may be used to remove the exposed portion 780 of the photosensitive organometallic oxide polymer film 765 using etch chemistries selective to the exposed portion 780. In some embodiments, the one or more features 785 may comprise a contact hole pattern, and the method 600 may use the contact hole pattern to form one or more contact holes within the one or more underlying layers 705 formed below the patterned layer 760, as shown in FIG. 8F. The contact holes may be formed within the underlying layers 705 using a wet or dry etch process, as is known in the art.

Embodiments of the present disclosure provide improved process flows and methods of forming a photosensitive organometallic oxide polymer film on a semiconductor substrate. Further embodiments utilize the photosensitive organometallic oxide polymer film in subsequent processing steps to form an EUV-active photoresist on a substrate, fill gaps within a patterned layer and/or create features (such as, e.g., holes, trenches, etc.) within a patterned layer.

The process flows and methods disclosed herein improve upon conventional methods of forming EUV-active photoresists and photosensitive materials by utilizing chemical vapor polymerization (CVP) to deposit metal oxide resist complexes on a substrate surface (or a patterned layer) using a low temperature, low ion energy plasma process. The low temperature, low ion energy plasma process uses a variety of metal precursors having carbon-carbon double bounds to form liquid-like oligomer units on the substrate surface (or patterned layer) which further polymerize upon heat treatment to form new organometallic compounds with improved photosensitivity, mechanical strength and stability compared to conventional EUV-active photoresists.

Using the process flows and methods disclosed herein, the new organometallic compounds are formed with excellent uniformity and better nucleation on the underlying surfaces (even hydrophobic surfaces). The process flows and methods disclosed herein also provide faster deposition on hydrophobic surfaces by using CVP to deposit liquid-like oligomer units on the substrate surface (or patterned layer), instead of depositing a rigid metal oxide film using traditional CVD or ALD. Although the new organometallic compounds described herein can be deposited at a wide variety of thicknesses (e.g., less than 10 nm up to several hundred nm), the process flows and methods disclosed herein may enable a thinner, more uniform photoresist coating to be deposited onto the substrate surface, which in turn, can be used to transfer sub-10 nm features to underlying layers of the substrate.

The term “substrate” as used herein means and includes a base material or construction upon which materials are formed. It will be appreciated that the substrate may include a single material, a plurality of layers of different materials, a layer or layers having regions of different materials or different structures in them, etc. These materials may include semiconductors, insulators, conductors, or combinations thereof. For example, the substrate may be a semiconductor substrate, a base semiconductor layer on a supporting structure, a metal electrode or a semiconductor substrate having one or more layers, structures or regions formed thereon. The substrate may be a conventional silicon substrate or other bulk substrate comprising a layer of semi-conductive material. As used herein, the term “bulk substrate” means and includes not only silicon wafers, but also silicon-on-insulator (“SOI”) substrates, such as silicon-on-sapphire (“SOS”) substrates and silicon-on-glass (“SOG”) substrates, epitaxial layers of silicon on a base semiconductor foundation, and other semiconductor or optoelectronic materials, such as silicon-germanium, germanium, gallium arsenide, gallium nitride, and indium phosphide. The substrate may be doped or undoped.

The substrate may also include any material portion or structure of a device, particularly a semiconductor or other electronics device, and may, for example, be a base substrate structure, such as a semiconductor substrate or a layer on or overlying a base substrate structure. Thus, the term “substrate” is not intended to be limited to any particular base structure, underlying layer or overlying layer, patterned layer or unpatterned layer, but rather, is contemplated to include any such layer or base structure, and any combination of layers and/or base structures.

It is noted that reference throughout this specification to “one embodiment” or “an embodiment” means that a particular feature, structure, material, or characteristic described in connection with the embodiment is included in at least one embodiment of the invention, but do not denote that they are present in every embodiment. Thus, the appearances of the phrases “in one embodiment” or “in an embodiment” in various places throughout this specification are not necessarily referring to the same embodiment of the invention. Furthermore, the particular features, structures, materials, or characteristics may be combined in any suitable manner in one or more embodiments. Various additional layers and/or structures may be included and/or described features may be omitted in other embodiments.

One skilled in the relevant art will recognize that the various embodiments may be practiced without one or more of the specific details, or with other replacement and/or additional methods, materials, or components. In other instances, well-known structures, materials, or operations are not shown or described in detail to avoid obscuring aspects of various embodiments of the invention. Similarly, for purposes of explanation, specific numbers, materials, and configurations are set forth in order to provide a thorough understanding of the invention. Nevertheless, the invention may be practiced without specific details. Furthermore, it is understood that the various embodiments shown in the figures are illustrative representations and are not necessarily drawn to scale.

Further modifications and alternative embodiments of the methods described herein will be apparent to those skilled in the art in view of this description. It will be recognized, therefore, that the described methods are not limited by these example arrangements. It is to be understood that the forms of the methods herein shown and described are to be taken as example embodiments. Various changes may be made in the implementations. Thus, although the inventions are described herein with reference to specific embodiments, various modifications and changes can be made without departing from the scope of the present inventions. Accordingly, the specification and figures are to be regarded in an illustrative rather than a restrictive sense, and such modifications are intended to be included within the scope of the present inventions. Further, any benefits, advantages, or solutions to problems that are described herein with regard to specific embodiments are not intended to be construed as a critical, required, or essential feature or element of any or all the claims.

What is claimed is:

1. A method for filling gaps within a patterned layer formed on a semiconductor substrate, the method comprising:
providing the semiconductor substrate, wherein the patterned layer formed on the semiconductor substrate comprises a plurality of structures, which are spaced apart and separated by gaps;
depositing a non-solid organometallic oxide polymer containing liquid-like oligomer units on the patterned layer via chemical vapor polymerization (CVP), wherein the liquid-like oligomer units flow into the gaps between the plurality of structures during said depositing, and wherein a capillary effect within the gaps causes the liquid-like oligomer units to completely fill the gaps with the non-solid organometallic oxide polymer; and
heat-treating the semiconductor substrate to further polymerize the non-solid organometallic oxide polymer and form a photosensitive organometallic oxide polymer film on the patterned layer and within the gaps between the plurality of structures.

2. The method of claim 1, wherein the photosensitive organometallic oxide polymer film contains a central metal atom of tin (Sn), zirconium (Zr), indium (In), antimony (Sb), bismuth (Bi), zinc (Zn), hafnium (Hf), or aluminum (Al), or combinations thereof.

3. The method of claim 1, wherein said depositing the non-solid organometallic oxide polymer comprises:
exposing the semiconductor substrate to a plasma-excited vapor comprising a metal precursor having carbon-carbon double bonds to form the non-solid organometallic oxide polymer on the patterned layer and within the gaps between the plurality of structures.

4. The method of claim 3, wherein said exposing the semiconductor substrate to the plasma-excited vapor comprises:
maintaining an ion energy of less than 50 eV in the plasma-excited vapor; and
maintaining a substrate temperature of less than 150° C. during the exposing.

5. The method of claim 3, wherein said exposing the semiconductor substrate to the plasma-excited vapor comprises:
maintaining an ion energy of between 0 eV and 5 eV in the plasma-excited vapor; and
maintaining a substrate temperature within a range between −50° C. and 0° C. during the exposing.

6. The method of claim 3, wherein the metal precursor includes a metal alkoxide.

7. The method of claim 3, wherein the metal precursor contains tin (Sn), and wherein the metal precursor:
(a) has a formula Sn_{α}O_{β} (O—CₘHₙ)ΓCₓH_{y}, where m, n, and α are arbitrary integers of 1 or more, β, Γ, x, and y are arbitrary integers of 0 or more, and β and Γ are not 0 at the same time;
(b) is SnR1(O—R2)₃, SnR1₂(O—R2)₂, or SnHR1(O—R2)₂, where R1: CH₃, C₂H₃, C₃H₅, C₄H₇, or C₆H₆, and R2: CH₃, C₂H₅, C₃H₇, or C₄H₉;
(c) is SnCH3^{t}Bu(O—^{t}Bu)₂, Sn^{t}Bu(O—^{t}Bu)₃, Sn^{t}Bu(O—C₃H₇)₃, Sn^{t}Bu(O—C₂H₅)₃, Sn^{t}Bu(O—CH₃)₃, SnCH₃C₂H₃(O—^{t}Bu)₂, or SnCH₃(C₂H₃)(O—CH₃)₂;
(d) is Sn(C₂H₄O₂) or Sn(OR)₂, where R is selected from CH₃, C₂H₅ and C₄H₉;
(e) is a mixture of Sn(N(CH₃)₂)₄ and HOCH₂CH₂OH;
(f) has a formula SnₓC_{y}H_{z}, where x, y, and z are arbitrary integers of 1 or more; or
(g) is Sn(CH₃)₄, Sn(C₂H₅)₄, SnH(CH₃)₃, or SnH(C₂H₅)₃.

8. The method of claim 3, wherein the plasma-excited vapor comprises the metal precursor and an additive precursor, wherein the metal precursor has a formula Sn_{α}O_{β} (O—CₘHₙ)ΓCₓH_{y}, and wherein the additive precursor has a formula Sn_{α}CₓH_{y}, where m, n, and α are arbitrary integers of 1 or more.

9. The method of claim 3, wherein the metal precursor contains a metal (M) and has a formula M_{α}O_{β} (O—CₘHₙ)ΓCₓH_{y}, where m, n, and α are arbitrary integers of 1 or more, β, Γ, x, and y are arbitrary integers of 0 or more, and β and Γ are not 0 at the same time.

10. The method of claim 9, wherein the plasma-excited vapor comprises the metal precursor and one or more additive precursors, and wherein the one or more additive precursors comprise:
(a) a precursor containing a metal (M) and having a formula M_{α}CₓH_{y}, where m, n, and α are arbitrary integers of 1 or more; and/or
(b) a nitrogen containing precursor.

11. The method of claim 3, wherein said heat-treating the semiconductor substrate comprises:
heat-treating the semiconductor substrate to a substrate temperature between about 0° C. and about 400° C. to further polymerize the non-solid organometallic oxide polymer and form the photosensitive organometallic oxide polymer film with polymerized carbon-carbon bonds on the patterned layer and within the gaps between the plurality of structures.

12. The method of claim 11, wherein said heat-treating the semiconductor substrate utilizes a plasma.

13. A method utilized in a self-aligned multi-patterning (SAMP) process flow, the method comprising:
forming a patterned layer on one or more underlying layers formed on a semiconductor substrate, wherein the patterned layer comprises a plurality of structures, which are formed during the SAMP process flow and separated by gaps;
depositing a non-solid organometallic oxide polymer containing liquid-like oligomer units on the patterned layer via chemical vapor polymerization (CVP), wherein the liquid-like oligomer units flow into the gaps between the plurality of structures during said depositing, and wherein a capillary effect within the gaps causes the liquid-like oligomer units to completely fill the gaps with the non-solid organometallic oxide polymer;
heat-treating the semiconductor substrate to further polymerize the non-solid organometallic oxide polymer and form a photosensitive organometallic oxide polymer film on the patterned layer and within the gaps between the plurality of structures;
selectively exposing the photosensitive organometallic oxide polymer film to extreme ultraviolet (EUV) radiation, wherein said selectively exposing changes an etch selectivity of a portion of the photosensitive organometallic oxide polymer film formed within one or more of the gaps; and
selectively etching the photosensitive organometallic oxide polymer film, wherein said selectively etching removes the portion of the photosensitive organometallic oxide polymer film from the one or more of the gaps to create one or more features on the one or more underlying layers.

14. The method of claim 13, wherein said selectively etching removes the portion of the photosensitive organometallic oxide polymer film from the one or more of the gaps to create a contact hole pattern on the one or more underlying layers, and wherein the method further comprises utilizing the contact hole pattern to form contact holes within the one or more underlying layers.

15. The method of claim 13, wherein the photosensitive organometallic oxide polymer film contains a central metal atom of tin (Sn), zirconium (Zr), indium (In), antimony (Sb), bismuth (Bi), zinc (Zn), hafnium (Hf), or aluminum (Al), or combinations thereof.

16. The method of claim 13, wherein said depositing the non-solid organometallic oxide polymer comprises:
exposing the semiconductor substrate to a plasma-excited vapor comprising a metal precursor having carbon-carbon double bonds to form the non-solid organometallic oxide polymer on the patterned layer and within the gaps between the plurality of structures.

17. The method of claim 16, wherein said exposing the semiconductor substrate to the plasma-excited vapor comprises:
maintaining an ion energy of less than 50 eV in the plasma-excited vapor; and
maintaining a substrate temperature of less than 150° C. during the exposing.

18. The method of claim 16, wherein said exposing the semiconductor substrate to the plasma-excited vapor comprises:
maintaining an ion energy of between 0 eV and 5 eV in the plasma-excited vapor; and
maintaining a substrate temperature within a range between −50° C. and 0° C. during the exposing.

19. The method of claim 16, wherein the metal precursor includes a metal alkoxide.

20. The method of claim 16, wherein the metal precursor contains tin (Sn), and wherein the metal precursor:
(a) has a formula Sn_{α}O_{β} (O—CₘHₙ)ΓCₓH_{y}, where m, n, and α are arbitrary integers of 1 or more, β, Γ, x, and y are arbitrary integers of 0 or more, and β and Γ are not 0 at the same time;
(b) is SnR1(O—R2)₃, SnR1₂(O—R2)₂, or SnHR1(O—R2)₂, where R1: CH₃, C₂H₃, C₃H₅, C₄H₇, or C₆H₆, and R2: CH₃, C₂H₅, C₃H₇, or C₄H₉;
(c) is SnCH3^{t}Bu(O—^{t}Bu)₂, Sn^{t}Bu(O—^{t}Bu)₃, Sn^{t}Bu(O—C₃H₇)₃, Sn^{t}Bu(O—C₂H₅)₃, Sn^{t}Bu(O—CH₃)₃, SnCH₃C₂H₃(O—^{t}Bu)₂, or SnCH₃(C₂H₃)(O—CH₃)₂;
(d) is Sn(C₂H₄O₂) or Sn(OR)₂, where R is selected from CH₃, C₂H₅and C₄H₉;
(e) is a mixture of Sn(N(CH₃)₂)₄ and HOCH₂CH₂OH;
(f) has a formula SnₓC_{y}H_{z}, where x, y, and z are arbitrary integers of 1 or more; or
(g) is Sn(CH₃)₄, Sn(C₂H₅)₄, SnH(CH₃)₃, or SnH(C₂H₅)₃.

21. The method of claim 16, wherein the plasma-excited vapor comprises the metal precursor and an additive precursor, wherein the metal precursor has a formula Sn_{α}O_{β} (O—CₘHₙ)ΓCₓH_{y}, and wherein the additive precursor has a formula Sn_{α}CₓH_{y}, where m, n, and α are arbitrary integers of 1 or more.

22. The method of claim 16, wherein the metal precursor contains a metal (M) and has a formula M_{α}O_{β} (O—CₘHₙ)ΓCₓH_{y}, where m, n, and α are arbitrary integers of 1 or more, β, Γ, x, and y are arbitrary integers of 0 or more, and β and Γ are not 0 at the same time.

23. The method of claim 22, wherein the plasma-excited vapor comprises the metal precursor and one or more additive precursors, and wherein the one or more additive precursors comprise:
(a) a precursor containing a metal (M) and having a formula M_{α}CₓH_{y}, where m, n, and α are arbitrary integers of 1 or more; and/or
(b) a nitrogen containing precursor.

24. The method of claim 16, wherein said heat-treating the semiconductor substrate comprises:
heat-treating the semiconductor substrate to a substrate temperature between about 0° C. and about 400° C. to further polymerize the non-solid organometallic oxide polymer and form the photosensitive organometallic oxide polymer film with polymerized carbon-carbon bonds on the patterned layer and within the gaps between the plurality of structures.

25. The method of claim 24, wherein said heat-treating the semiconductor substrate utilizes a plasma.
